(19) United States
(12) Patent Application Publication
(10) Pub. No.: US 2023/0035562 A1
(43) Pub. Date: Feb. 2, 2023

(54) SUBSTRATE PROCESSING METHOD AND SUBSTRATE PROCESSING DEVICE

(71) Applicant: SCREEN Holdings Co., Ltd., Kyoto (JP)

(72) Inventors: Shigeru YAMAMOTO, Kyoto-shi (JP); Keiji IWATA, Kyoto-shi (JP); Daiki FUJII, Kyoto-shi (JP); Kenji EDAMITSU, Kyoto-shi (JP); Yuya KAWAI, Kyoto-shi (JP); Kenichi ITO, Kyoto-shi (JP)

(73) Assignee: SCREEN Holdings Co., Ltd., Kyoto (JP)

(21) Appl. No.: 17/876,547

(22) Filed: Jul. 29, 2022

(30) Foreign Application Priority Data
Jul. 30, 2021 (JP) 2021-125536

(51) Int. Cl. B05C 3/10; B05C 3/00; B05C 15/00

(52) U.S. Cl. CPC B05C 3/10; B05C 3/005; B05C 15/00

(57) ABSTRACT

The substrate treatment method includes a first decompressing step, a first pressurizing step, and a first atmospheric pressure step. In the first decompressing step, the inside of a chamber is in a decompressed state, and a first gas is supplied to a substrate inside the chamber. The first gas includes an organic solvent. The first pressurizing step is executed after the first decompressing step. In the first pressurizing step, mixed gas is supplied to the substrate inside the chamber, and the inside of the chamber is pressurized from the decompressed state to an atmospheric pressure state. The mixed gas includes an organic solvent and inert gas. The first atmospheric pressure step is executed after the first pressurizing step. In the first atmospheric pressure step, the inside of the chamber is maintained in the atmospheric pressure state, and at least any of liquid discharge treatment and substrate treatment is performed.

### CROSS-REFERENCE TO RELATED APPLICATION

This application claims the priority benefit of Japan application serial no. 2021-125536, filed on Jul. 30, 2021. The entirety of the above-mentioned patent application is hereby incorporated by reference herein and made a part of this specification.

### BACKGROUND

### Technical Field

The disclosure relates to a substrate treatment method and a substrate treatment device. Examples of a substrate include semiconductor wafers, substrates for liquid crystal displays, substrates for organic electroluminescence (EL), substrates for flat panel displays (FPD), substrates for optical displays, substrates for magnetic disks, substrates for optical discs, substrates for magneto-optical discs, substrates for photomasks, and substrates for solar batteries.

### Description of Related Art

Japanese Patent Laid-Open No. 2018-56155 discloses a substrate treatment method for treating a substrate accommodated inside a chamber. The substrate treatment method includes a first step, a second step, and a drying step. In the first step, vapor of a hydrophobizing agent is supplied to a substrate in a state in which the inside of the chamber is decompressed (decompressed state). In the second step, vapor of an organic solvent is supplied to a substrate in a state in which the inside of the chamber is decompressed. In the drying step, inert gas is supplied to a substrate in a state in which the inside of the chamber is decompressed.

Here, in the first step and the second step, a substrate does not dry. In the drying step, a substrate dries.

In the substrate treatment method, an exhaust pump is used for causing the inside of the chamber to be in a decompressed state. The exhaust pump discharges gas inside the chamber to the outside of the chamber. The exhaust pump operates in the first step, the second step, and the drying step.

After the drying step, the inside of a chamber 3 is pressurized from a decompressed state to an atmospheric pressure state. In order to pressurize the inside of the chamber 3 from a decompressed state to an atmospheric pressure state, the following operations A and B are executed.

Operation A: stopping operation of the exhaust pump

Operation B: supplying inert gas to the inside of the chamber

### SUMMARY

### Technical Problem

Japanese Patent Laid-Open No. 2018-56155 does not disclose pressurization of the inside of a chamber from a decompressed state to an atmospheric pressure state after a first step and before a drying step. Japanese Patent Laid-Open No. 2018-56155 does not disclose pressurization of the inside of the chamber from a decompressed state to an atmospheric pressure state before a substrate dries after treatment with respect to the substrate has started.

The disclosure has been made in consideration of such circumstances and provides a substrate treatment method and a substrate treatment device capable of appropriately pressurizing the inside of a chamber from a decompressed state to an atmospheric pressure state.

### Solution to Problem

The inventors have achieved the following knowledge as a result of intensive studies for resolving the foregoing problems. For example, in order to perform liquid discharge treatment after a first step and before a second step, it may be preferable that the inside of a chamber be in an atmospheric pressure state after the first step and before the second step. For example, in order to improve the quality of substrate treatment in the second step, it may be preferable that the inside of the chamber be in an atmospheric pressure state in the second step. Hence, the inventors have reviewed pressurization of the inside of the chamber from a decompressed state to an atmospheric pressure state after the first step and before the second step. For example, the inventors have reviewed execution of an additional step after the first step and before the second step. The additional step includes the operations A and B described above.

However, the inventors have found that the additional step has new problems. The new problems are as follows. A substrate is exposed to inert gas and dries in the additional step. The additional step is executed after the first step and before the second step. When a substrate dries after the first step and before the second step, there is concern that a substrate may not be appropriately treated in the second step. There is concern that it may be difficult to maintain the quality of substrate treatment in the second step. There is concern that the quality of substrate treatment in the second step may be degraded.

The disclosure has been obtained through further intensive studies based on the knowledge and has the following constitutions. That is, the disclosure provides a substrate treatment method for simultaneously treating a plurality of substrates accommodated in one chamber. The substrate treatment method includes a first decompressing step of supplying a first gas including an organic solvent to the substrate inside the chamber in a state in which the inside of the chamber is decompressed, a first pressurizing step of supplying mixed gas including an organic solvent and inert gas to the substrate inside the chamber and pressurizing the inside of the chamber from a decompressed state to an atmospheric pressure state after the first decompressing step, and a first atmospheric pressure step of maintaining the inside of the chamber in an atmospheric pressure state and performing at least any of liquid discharge treatment and substrate treatment after the first pressurizing step.

The substrate treatment method is a method for simultaneously treating a plurality of substrates accommodated in one chamber. The substrate treatment method includes the first decompressing step, the first pressurizing step, and the first atmospheric pressure step. The first decompressing step, the first pressurizing step, and the first atmospheric pressure step are executed in this order.

In the first decompressing step, the inside of the chamber is in a decompressed state. In the first decompressing step, the first gas is supplied to the substrate inside the chamber. The first gas includes an organic solvent. The organic solvent of the first gas adheres to the substrate and moistens the substrate. For this reason, in the first decompressing step, the substrate does not dry.

In the first pressurizing step, the inside of the chamber is pressurized from a decompressed state to an atmospheric pressure state. In the first pressurizing step, mixed gas is supplied to the substrate inside the chamber. The mixed gas includes an organic solvent and inert gas. The inert gas of the mixed gas quickly pressurizes the inside of the chamber from a decompressed state to an atmospheric pressure state. The organic solvent of the mixed gas adheres to the substrate and moistens the substrate. For this reason, in the first pressurizing step, the inside of the chamber quickly shifts to an atmospheric pressure state without causing the substrate to dry. In the first pressurizing step, the substrate does not dry. Thus, the substrate does not dry after the first decompressing step and before the first atmospheric pressure step.

In the first atmospheric pressure step, the inside of the chamber is maintained in an atmospheric pressure state. In the first atmospheric pressure step, at least any of the liquid discharge treatment and the substrate treatment is performed. When the liquid discharge treatment is performed in the first atmospheric pressure step, it is easy to perform the liquid discharge treatment in the first atmospheric pressure step. This is because the inside of the chamber is maintained in an atmospheric pressure state. More specifically, when the inside of the chamber is in an atmospheric pressure state, the pressure of gas inside the chamber is close to the pressure of gas outside the chamber. When the substrate treatment is performed in the first atmospheric pressure step, the substrate treatment in the first atmospheric pressure step is performed with appropriate quality. This is because the substrate does not dry in the first pressurizing step. This is because the substrate does not dry after the first decompressing step and before the first atmospheric pressure step.

As above, in the substrate treatment method, the inside of the chamber can be appropriately pressurized from a decompressed state to an atmospheric pressure state. Specifically, in the substrate treatment method, the inside of the chamber can be quickly pressurized from a decompressed state to an atmospheric pressure state without causing the substrate to dry. Therefore, the first atmospheric pressure step is favorably executed after the inside of the chamber has shifted to an atmospheric pressure state.

According to the substrate treatment method described above, it is preferable that the mixed gas include at least any of gas of the organic solvent and liquid of the organic solvent. When the mixed gas includes gas of the organic solvent, the gas of the organic solvent in the mixed gas is dew-condensed on a surface of the substrate and changes to liquid of the organic solvent on the surface of the substrate. When the mixed gas includes liquid of the organic solvent, the liquid of the organic solvent in the mixed gas adheres to the surface of the substrate. Even when the mixed gas includes gas of the organic solvent, or even when the mixed gas includes liquid of the organic solvent, the organic solvent derived from the mixed gas favorably moistens the substrate. Thus, the mixed gas favorably prevents the substrate from drying.

According to the substrate treatment method described above, it is preferable that in the first pressurizing step, the mixed gas be generated and the generated mixed gas be supplied to the inside of the chamber by a first emission part. In the first pressurizing step, the inert gas supplied to the inside of the chamber is accompanied by the organic solvent. In the first pressurizing step, the inert gas supplied to the inside of the chamber is not separated from the organic solvent. In the first pressurizing step, the inert gas and the organic solvent are not individually supplied to the inside of the chamber. For this reason, in the first pressurizing step, the substrate is more reliably prevented from drying.

According to the substrate treatment method described above, it is preferable that in the first pressurizing step, the substrate be further vertically moved or swung inside the chamber. In the first pressurizing step, the organic solvent derived from the mixed gas adheres more uniformly to the entire substrate.

According to the substrate treatment method described above, it is preferable to further include a first dipping step of dipping the substrate into a first liquid stored in a treatment tank installed inside the chamber before the first decompressing step. It is preferable that the first atmospheric pressure step further include a first liquid discharging step of discharging the first liquid to the outside of the chamber. The first atmospheric pressure step includes the first liquid discharging step. In the first atmospheric pressure step, the inside of the chamber is maintained in an atmospheric pressure state. For this reason, in the first liquid discharging step, the inside of the chamber is maintained in an atmospheric pressure state. Therefore, in the first liquid discharging step, it is easy to discharge the first liquid inside the chamber to the outside of the chamber.

Treatment in the first liquid discharging step corresponds to the liquid discharge treatment in the first atmospheric pressure step. Thus, it is easy to perform the liquid discharge treatment in the first atmospheric pressure step.

According to the substrate treatment method described above, it is preferable that in the first liquid discharging step, a liquid discharge tube which communicates with and is connected to any of the chamber and the treatment tank be open to atmospheric air outside the chamber and the first liquid be discharged to the outside of the chamber through the liquid discharge tube. In the first liquid discharging step, the liquid discharge tube is open to the atmospheric air outside the chamber. As described above, in the first liquid discharging step, the inside of the chamber is in an atmospheric pressure state. Thus, in the first liquid discharging step, it is easy to discharge the first liquid inside the chamber to the outside of the chamber through the liquid discharge tube.

Here, for example, the first liquid inside the chamber includes the first liquid stored in the treatment tank. When the liquid discharge tube communicates with and is connected to the treatment tank, the first liquid stored in the treatment tank is discharged to the outside of the chamber through the liquid discharge tube. For example, the first liquid inside the chamber includes the first liquid which has been released from the treatment tank and has been accumulated in the chamber. When the liquid discharge tube communicates with and is connected to the chamber, the first liquid accumulated in the chamber is discharged to the outside of the chamber through the liquid discharge tube.

According to the substrate treatment method described above, it is preferable that in the first decompressing step, the substrate be picked up from the first liquid to above the treatment tank in a state in which the inside of the chamber is decompressed. The treatment tank stores the first liquid until the substrate is picked up from the first liquid inside the treatment tank in the first decompressing step. Here, when the substrate is picked up from the first liquid inside the treatment tank in the first decompressing step, the inside of the chamber is already in a decompressed state. The treatment tank stores the first liquid until the inside of the chamber shifts to a decompressed state. As long as the inside of the chamber is in a decompressed state, it is difficult to discharge the first liquid from the inside of the chamber to the outside of the chamber. However, the first pressurizing step is executed after the first decompressing step and before the first liquid discharging step. For this reason, it is easy to execute the first liquid discharging step. In this manner, when the treatment tank stores the first liquid until the inside of the chamber is in a decompressed state, the first pressurizing step is extremely useful.

According to the substrate treatment method described above, it is preferable to further include a first atmosphere forming step of forming an atmosphere of the first gas inside the chamber in a state in which the substrate is dipped into the first liquid before the first decompressing step. In the first decompressing step, the substrate is exposed to the atmosphere of the first gas from when the substrate is picked up from the first liquid inside the treatment tank. Thus, the quality of the substrate treatment in the first decompressing step is favorably improved.

According to the substrate treatment method described above, it is preferable that the first atmospheric pressure step further include a supplying step of supplying the second liquid to the treatment tank after the first liquid discharging step. The supplying step is executed after the first liquid discharging step. For this reason, the second liquid is supplied to the treatment tank after the first liquid inside the chamber is discharged to the outside of the chamber. Thus, it is easy to supply the second liquid to the treatment tank in the supplying step. The supplying step is included in the first atmospheric pressure step. For this reason, the inside of the chamber is in an atmospheric pressure state in the supplying step. Thus, it is easier to supply the second liquid to the treatment tank in the supplying step. As a result, it is easy to store the second liquid in the treatment tank in the supplying step. It is easy to replace the first liquid with the second liquid in the treatment tank by a combination of the first liquid discharging step and the supplying step.

According to the substrate treatment method described above, it is preferable that the first atmospheric pressure step further include a second dipping step of dipping the substrate into the second liquid stored in the treatment tank. As described above, the substrate does not dry after the first decompressing step and before the first atmospheric pressure step. The first atmospheric pressure step includes the second dipping step. Thus, in the second dipping step, the substrate is treated with appropriate quality.

Treatment in the second dipping step corresponds to the substrate treatment in the first atmospheric pressure step. Thus, the substrate treatment in the first atmospheric pressure step is performed with appropriate quality. As a result, in the first atmospheric pressure step, the liquid discharge treatment and the substrate treatment are favorably performed.

According to the substrate treatment method described above, it is preferable that an atmosphere inside the chamber include an organic solvent until the substrate is dipped into the second liquid from the first pressurizing step. The organic solvent included in the atmosphere inside the chamber moistens the substrate until the substrate is dipped into the second liquid from the first pressurizing step. Thus, the substrate does not dry from the first pressurizing step to the second dipping step. After the first decompressing step and before the second dipping step, the substrate does not dry. Therefore, in the second dipping step, the substrate is treated with appropriate quality.

According to the substrate treatment method described above, it is preferable that the mixed gas be further supplied to the substrate inside the chamber until the substrate is dipped into the second liquid from the first pressurizing step. For this reason, the atmosphere inside the chamber favorably includes the organic solvent until the substrate is dipped into the second liquid inside the treatment tank from the first pressurizing step.

According to the substrate treatment method described above, it is preferable that in the second dipping step, the second liquid be further discharged to the outside of the chamber. The second dipping step is included in the first atmospheric pressure step. For this reason, in the second dipping step, the inside of the chamber is in an atmospheric pressure state. Thus, in the second dipping step, it is easy to discharge the second liquid inside the chamber to the outside of the chamber.

Discharging of the second liquid to the outside of the chamber in the second dipping step corresponds to the liquid discharge treatment in the first atmospheric pressure step. Thus, it is easy to perform the liquid discharge treatment in the first atmospheric pressure step.

According to the substrate treatment method described above, it is preferable that in the second dipping step, the second liquid overflow from the treatment tank and the second liquid which has overflowed from the treatment tank be discharged to the outside of the chamber. In the second dipping step, it is easy to cleanly maintain the second liquid in the treatment tank. Thus, the quality of the substrate treatment in the second dipping step is favorably improved.

According to the substrate treatment method described above, it is preferable that in the second dipping step, a liquid discharge tube which communicates with and is connected to any of the chamber and the treatment tank be open to atmospheric air outside the chamber and the second liquid be discharged to the outside of the chamber through the liquid discharge tube. In the second dipping step, the liquid discharge tube is open to the atmospheric air outside the chamber. As described above, in the second dipping step, the inside of the chamber is in an atmospheric pressure state. Thus, in the second dipping step, it is easy to discharge the second liquid inside the chamber to the outside of the chamber through the liquid discharge tube.

Here, for example, the second liquid inside the chamber includes the second liquid stored in the treatment tank. When the liquid discharge tube communicates with and is connected to the treatment tank, the second liquid stored in the treatment tank is discharged to the outside of the chamber through the liquid discharge tube. For example, the second liquid inside the chamber includes the second liquid which has been released from the treatment tank and has been accumulated in the chamber. When the liquid discharge tube communicates with and is connected to the chamber, the second liquid accumulated in the chamber is discharged to the outside of the chamber through the liquid discharge tube.

According to the substrate treatment method described above, it is preferable to further include a second decompressing step of dipping the substrate into a second liquid stored in a treatment tank installed inside the chamber in a state in which the inside of the chamber is decompressed after the first atmospheric pressure step. As described above, the substrate does not dry in the first pressurizing step. Moreover, the inside of the chamber is maintained in an atmospheric pressure state in the first atmospheric pressure step. For this reason, the substrate is unlikely to dry in the first atmospheric pressure step. The second decompressing step is executed after the first atmospheric pressure step. Thus, the substrate is unlikely to dry after the first decompressing step and before the second decompressing step. Therefore, it is easy to treat the substrate with appropriate quality in the second decompressing step.

According to the substrate treatment method described above, it is preferable that an atmosphere inside the chamber include an organic solvent until the substrate is dipped into the second liquid from the first pressurizing step. The organic solvent included in the atmosphere inside the chamber moistens the substrate until the substrate is dipped into the second liquid from the first pressurizing step. Thus, the substrate does not dry from the first pressurizing step to the second decompressing step. The substrate does not dry after the first decompressing step and before the second decompressing step. Therefore, in the second decompressing step, the substrate is treated with appropriate quality.

According to the substrate treatment method described above, it is preferable that the mixed gas be further supplied to the substrate inside the chamber until the substrate is dipped into the second liquid from the first pressurizing step. For this reason, the atmosphere inside the chamber favorably includes the organic solvent until the substrate is dipped into the second liquid inside the treatment tank from the first pressurizing step.

The disclosure provides a substrate treatment device including a chamber that accommodates a plurality of substrates, a decompression unit that decompresses the inside of the chamber, a first supply unit that supplies a first gas including an organic solvent to the substrate inside the chamber, a second supply unit that supplies mixed gas including an organic solvent and inert gas to the substrate inside the chamber, and a control part that controls the decompression unit, the first supply unit, and the second supply unit to execute first decompressing treatment and first pressurizing treatment. In the first decompressing treatment, the decompression unit decompresses the inside of the chamber, and the first supply unit supplies the first gas to the substrate. In the first pressurizing treatment, the decompression unit does not decompress the inside of the chamber, and the second supply unit supplies the mixed gas to the substrate.

The control part is constituted to execute the first decompressing treatment and the first pressurizing treatment. In the first decompressing treatment, the decompression unit decompresses the inside of the chamber. For this reason, in the first decompressing treatment, the inside of the chamber shifts to a decompressed state. In the first decompressing treatment, the first supply unit supplies the first gas to the substrate inside the chamber. The first gas includes an organic solvent. The organic solvent of the first gas adheres to the substrate and moistens the substrate. For this reason, in the first decompressing step, the substrate does not dry. In the first pressurizing treatment, the decompression unit does not decompress the inside of the chamber. In the first pressurizing treatment, the second supply unit supplies mixed gas to the substrate. The mixed gas includes an organic solvent and inert gas. The inert gas of the mixed gas quickly raises the pressure of gas inside the chamber. The organic solvent of the mixed gas adheres to the substrate and moistens the substrate. For this reason, in the first pressurizing treatment, the substrate does not dry. In the first pressurizing treatment, the inside of the chamber is quickly pressurized from a decompressed state to an atmospheric pressure state without causing the substrate to dry.

As above, in the substrate treatment device, the inside of the chamber can be appropriately pressurized from a decompressed state to an atmospheric pressure state. Specifically, in the substrate treatment device, the inside of the chamber can be quickly pressurized from a decompressed state to an atmospheric pressure state without causing the substrate to dry. Therefore, even when additional treatment is performed with respect to the substrate after the first pressurizing treatment, it is easy to perform the additional treatment with appropriate quality.

### BRIEF DESCRIPTION OF THE DRAWINGS

Several forms which are currently preferred are illustrated in order to describe the disclosure. However, it should be understood that the disclosure is not limited to the illustrated constitutions and measures.

FIG. 1 is a front view illustrating the inside of a substrate treatment device of a first embodiment.

FIG. 2 is a control block diagram of the substrate treatment device.

FIG. 3 is a flowchart showing a procedure of a substrate treatment method of the first embodiment.

FIGS. 4A to 4E are views each of which schematically illustrates the substrate treatment device performing the substrate treatment method of the first embodiment.

FIG. 5 is a front view illustrating the inside of the substrate treatment device of a second embodiment.

FIG. 6 is a flowchart showing a procedure of the substrate treatment method of the second embodiment.

FIGS. 7A to 7D are views each of which schematically illustrates the substrate treatment device performing the substrate treatment method of the second embodiment.

FIG. 8 is a front view illustrating the inside of the substrate treatment device of a third embodiment.

FIG. 9 is a flowchart showing a procedure of the substrate treatment method of the third embodiment.

FIG. 10 is a flowchart showing another procedure of the substrate treatment method of the third embodiment.

FIGS. 11A to 11E are views each of which schematically illustrates the substrate treatment device performing the substrate treatment method of the third embodiment.

FIG. 12A-12E are views each of which schematically illustrates the substrate treatment device performing the substrate treatment method of the third embodiment.

FIG. 13A-13E are views each of which schematically illustrates the substrate treatment device performing the substrate treatment method of the third embodiment.

FIG. 14A-14B are views each of which schematically illustrates the substrate treatment device performing the substrate treatment method of the third embodiment.

### DESCRIPTION OF THE EMBODIMENT

Hereinafter, a substrate treatment method and a substrate treatment device of the disclosure will be described with reference to the drawings.

### 1. First Embodiment

<1-1. Overview of Substrate Treatment Device>

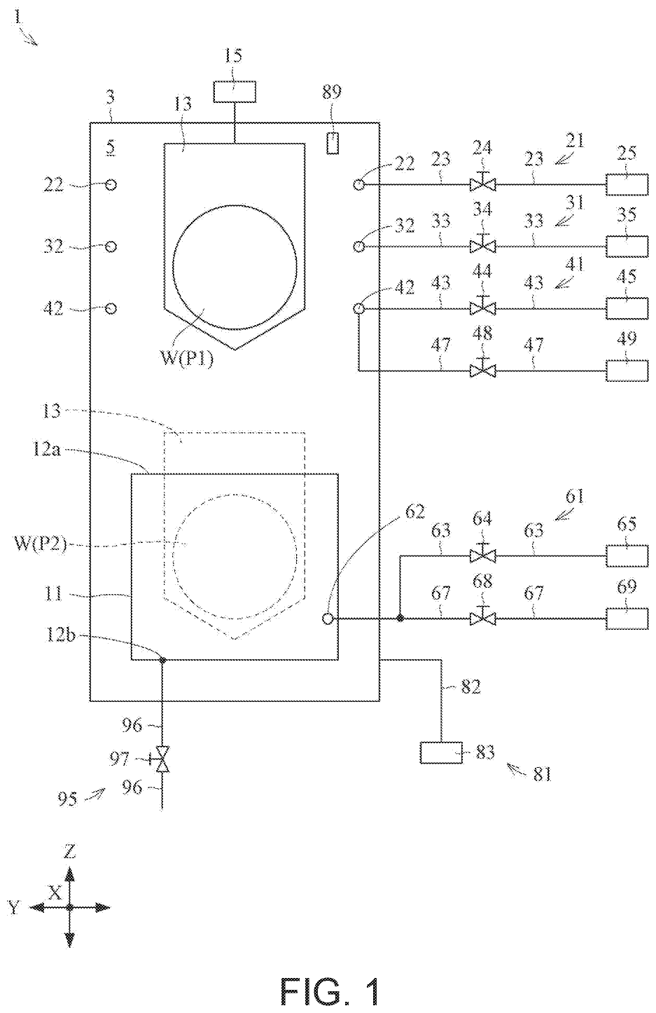

FIG. 1 is a front view illustrating the inside of a substrate treatment device 1 of a first embodiment. The substrate treatment device 1 performs treatment of a substrate W. The treatment performed by the substrate treatment device 1 includes drying treatment. The treatment performed by the substrate treatment device 1 may further include washing treatment. The substrate treatment device 1 is classified into a batch type. The substrate treatment device 1 simultaneously performs treatment of a plurality of substrates W.

Examples of the substrate W include semiconductor wafers, substrates for liquid crystal displays, substrates for organic electroluminescence (EL), substrates for flat panel displays (FPD), substrates for optical displays, substrates for magnetic disks, substrates for optical discs, substrates for magneto-optical discs, substrates for photomasks, and substrates for solar batteries.

The substrate W has a flat plate shape. The substrate W has substantially a circular shape in a front view.

The substrate W has a surface. The surface of the substrate W includes at least any of a silicon oxide film, a polysilicon film, a silicon nitride film, and a metal film.

Although illustration is omitted, the substrate W has a pattern. The pattern is formed on the surface of the substrate W. The pattern has an uneven shape. The surface of the substrate W on which the pattern is formed will be referred to as a pattern formation surface.

The substrate treatment device 1 includes a chamber 3. The chamber 3 accommodates a plurality of substrates W. The chamber 3 simultaneously accommodates a plurality of substrates W. The substrate W is disposed inside the chamber 3. Specifically, the chamber 3 is a container in which a space 5 is partitioned. The space 5 corresponds to the inside of the chamber 3. The substrate W is disposed in the space 5.

The chamber 3 is constituted to be able to be opened and closed. When the chamber 3 is opened, the space 5 is open. When the chamber 3 is opened, the chamber 3 allows the substrate W to move between the space 5 and the outside of the chamber 3. When the chamber 3 is closed, the space 5 is sealed. That is, the chamber 3 is constituted to be able to be sealed.

The substrate treatment device 1 includes a treatment tank 11. The treatment tank 11 is installed inside the chamber 3. The treatment tank 11 stores a treatment liquid. The treatment tank 11 is open upward.

Specifically, the treatment tank 11 has an opening 12a and a discharge port 12b. The opening 12a is disposed in an upper part of the treatment tank 11. The discharge port 12b is disposed in a bottom part of the treatment tank 11.

The substrate treatment device 1 includes a holding part 13. The holding part 13 is installed inside the chamber 3. The holding part 13 simultaneously holds a plurality of substrates W. The holding part 13 holds each of the substrates W substantially in a vertical posture. When the holding part 13 holds the substrate W, the pattern formation surface of the substrate W is substantially vertical. When the holding part 13 holds a plurality of substrates W, the plurality of substrates W is arranged in a row in a direction X. The direction X is a horizontal direction. The direction X is substantially perpendicular to the pattern formation surface of the substrate W.

In FIG. 1, in addition to the direction X, a direction Y and a direction Z are indicated. The direction Y is a horizontal direction. The direction Y is perpendicular to the direction X. The direction Z is a vertical direction. The direction Z is perpendicular to the direction X. The direction Z is perpendicular to the direction Y. The direction Z will be suitably referred to as a vertical direction Z.

The substrate treatment device 1 includes a lifting/lowering mechanism 15. The lifting/lowering mechanism 15 lifts and lowers the holding part 13. For example, the lifting/lowering mechanism 15 moves the holding part 13 in the vertical direction Z. When the lifting/lowering mechanism 15 lifts and lowers the holding part 13, the substrate W held by the holding part 13 is integrally lifted and lowered with the holding part 13.

The lifting/lowering mechanism 15 moves the substrate W between a first position P1 and a second position P2. When the substrate W moves between the first position P1 and the second position P2, the substrate W passes through the opening 12a. In FIG. 1, the substrate W at the first position P1 is indicated by a solid line. In FIG. 1, the substrate W at the second position P2 is indicated by a dashed line. The first position P1 is positioned inside the chamber 3. The first position P1 is positioned above the treatment tank 11. When the substrate W is positioned at the first position P1, the entire substrate W does not come into contact with the treatment liquid inside the treatment tank 11. The second position P2 is positioned inside the chamber 3. The second position P2 is positioned below the first position P1. The second position P2 is positioned inside the treatment tank 11. When the substrate W is positioned at the second position P2, the entire substrate W is dipped into the treatment liquid inside the treatment tank 11.

The substrate treatment device 1 includes supply units 21, 31, 41, and 61. The supply unit 21 supplies the inert gas to the chamber 3. The supply unit 31 supplies treatment gas to the chamber 3. The supply unit 41 supplies mixed gas to the chamber 3. The supply unit 61 supplies a first liquid and a second liquid to the treatment tank 11.

When the substrate W is positioned at the first position P1, the supply unit 21 supplies the inert gas to the substrate W. When the substrate W is positioned at the first position P1, the supply unit 31 supplies the treatment gas to the substrate W. When the substrate W is positioned at the first position P1, the supply unit 41 supplies the mixed gas to the substrate W.

The supply unit 31 is an example of a first supply unit according to the disclosure. The supply unit 41 is an example of a second supply unit according to the disclosure.

For example, the inert gas supplied by the supply unit 21 is nitrogen gas.

The treatment gas supplied by the supply unit 31 will be described. The treatment gas includes an organic solvent. The treatment gas includes gas of the organic solvent. For example, gas of the organic solvent is vapor of the organic solvent. For example, the concentration of the organic solvent in the treatment gas is high. For example, the treatment gas practically consists of only gas of the organic solvent. For example, the treatment gas practically includes no water (water vapor). It is preferable that the organic solvent of the treatment gas be hydrophilic. For example, the organic solvent of the treatment gas is isopropyl alcohol (IPA).

The mixed gas supplied by the supply unit 41 will be described. The mixed gas includes an organic solvent and inert gas. The mixed gas is a mixture of an organic solvent and inert gas. For example, the organic solvent of the mixed gas is isopropyl alcohol (IPA). For example, the inert gas of the mixed gas is nitrogen gas.

In the first embodiment, the mixed gas includes liquid of the organic solvent. That is, the organic solvent of the mixed gas is in a liquid phase. For example, the organic solvent in the mixed gas is at least any of droplets of the organic solvent or mist of the organic solvent.

The first liquid supplied by the supply unit 61 will be described. For example, the first liquid is a rinse liquid. For example, the first liquid is deionized water (DIW).

The second liquid supplied by the supply unit 61 will be described. The second liquid is a diluted organic solvent. For example, the second liquid is an organic solvent diluted with deionized water. For example, the second liquid is a mixed liquid of deionized water and an organic solvent. For example, the organic solvent of the second liquid is isopropyl alcohol (IPA).

A structure of the supply unit 21 will be described as an example. The supply unit 21 has an emission part 22. The emission part 22 is installed inside the chamber 3. The emission part 22 is disposed at a position higher than the treatment tank 11. The emission part 22 is disposed on both sides of the substrate W positioned at the first position P1 in the direction Y. The emission part 22 emits the inert gas to the inside of the chamber 3. The emission part 22 includes a tubular member. The tubular member extends in the direction X. The tubular member has a plurality of emission ports (not illustrated). The plurality of emission ports is arranged in the direction X. The emission part 22 emits the inert gas through the plurality of emission ports.

The supply unit 21 includes a pipe 23 and a valve 24. The pipe 23 is connected to the emission part 22. The pipe 23 is also connected to a supply source 25. The supply source 25 stores the inert gas. The valve 24 is provided in the pipe 23. When the valve 24 is opened, the inert gas flows from the supply source 25 to the emission part 22 through the pipe 23. When the valve 24 is opened, the emission part 22 emits the inert gas. When the valve 24 is closed, the inert gas does not flow from the supply source 25 to the emission part 22 through the pipe 23. When the valve 24 is closed, the emission part 22 does not emit the inert gas.

A structure of the supply unit 31 will be described as an example. The supply unit 31 has an emission part 32. The emission part 32 is installed inside the chamber 3. The emission part 32 is disposed at a position higher than the treatment tank 11. The emission part 32 is disposed on both sides of the substrate W positioned at the first position P1 in the direction Y. The emission part 32 emits the treatment gas to the inside of the chamber 3. For example, the emission part 32 has a structure similar to the structure of the emission part 22.

The supply unit 31 includes a pipe 33 and a valve 34. The pipe 33 is connected to the emission part 32. The pipe 33 is also connected to a supply source 35. The supply source 35 stores the treatment gas. The valve 34 is provided in the pipe 33. The valve 34 controls emission of the treatment gas performed by the emission part 32.

The supply source 35 may also generate treatment gas. Although illustration is omitted, for example, the supply source 35 includes a tank and a heater. The tank communicates with and is connected to the pipe 33. The tank stores liquid of the organic solvent. The heater warms liquid of the organic solvent inside the tank. Inside the tank, liquid of the organic solvent is vaporized and becomes vapor of the organic solvent. That is, treatment gas is generated inside the tank.

A structure of the supply unit 41 will be described as an example. The supply unit 41 has an emission part 42. The emission part 42 is installed inside the chamber 3. The emission part 42 is disposed at a position higher than the treatment tank 11. The emission part 42 is disposed on both sides of the substrate W positioned at the first position P1 in the direction Y. The emission part 42 emits the mixed gas into the chamber 3. The emission part 42 includes a plurality of (for example, 20) two-fluid nozzles. The plurality of two-fluid nozzles is arranged in two rows in the direction X. Each of the two-fluid nozzles generates mixed gas by mixing liquid of the organic solvent and the inert gas. For example, each of the two-fluid nozzles generates at least any of droplets of the organic solvent and mist of the organic solvent. Each of the two-fluid nozzles has one emission port (not illustrated). Each of the two-fluid nozzles emits the mixed gas through the emission port. Each of the two-fluid nozzles emits both the organic solvent and the inert gas through the emission port. Each of the two-fluid nozzles simultaneously emits both the organic solvent and the inert gas through the emission port. Each of the two-fluid nozzles does not individually emit the organic solvent and the inert gas. Each of the two-fluid nozzles injects at least any of droplets of the organic solvent and mist of the organic solvent together with the inert gas.

The emission part 42 is an example of a first emission part according to the disclosure.

The supply unit 41 includes pipes 43 and 47 and valves 44 and 48. Each of the pipes 43 and 47 is connected to the emission part 42. The pipe 43 is also connected to a supply source 45. The supply source 45 stores liquid of the organic solvent. The valve 44 is provided in the pipe 43. The valve 44 controls supplying of the organic solvent to the emission part 42. The pipe 47 is also connected to a supply source 49. The supply source 49 stores the inert gas. The valve 48 is provided in the pipe 47. The valve 48 controls supplying of the inert gas to the emission part 42. When the valves 44 and 48 are simultaneously opened, the emission part 42 emits the mixed gas.

A structure of the supply unit 61 will be described as an example. The supply unit 61 has an emission part 62. The emission part 62 is installed inside the chamber 3. The emission part 62 is installed inside the treatment tank 11. The emission part 62 emits the first liquid and the second liquid to the treatment tank 11.

The supply unit 61 includes a pipe 63 and a valve 64. The pipe 63 is connected to the emission part 62. The pipe 63 is also connected to a supply source 65. The supply source 65 stores the first liquid. The valve 64 is provided in the pipe 63. The valve 64 controls emission of the first liquid performed by the emission part 62. Similarly, the supply unit 61 includes a pipe 67 and a valve 68. The pipe 67 is connected to the emission part 62. The pipe 67 is also connected to a supply source 69. The supply source 69 stores the second liquid. The valve 68 is provided in the pipe 67. The valve 68 controls emission of the second liquid performed by the emission part 62.

The substrate treatment device 1 includes a decompression unit 81. The decompression unit 81 decompresses the inside of the chamber 3. Specifically, the decompression unit 81 discharges gas inside the chamber 3 to the outside of the chamber 3. Here, when the decompression unit 81 decompresses the inside of the chamber 3, the pressure of the gas inside the chamber 3 may continuously decrease or may not continuously decrease. When the decompression unit 81 decompresses the inside of the chamber 3, for example, the pressure of the gas inside the chamber 3 may be maintained within a predetermined negative pressure range.

A structure of the decompression unit 81 will be described as an example. The decompression unit 81 includes a pipe 82 and an exhaust pump 83. The pipe 82 and the exhaust pump 83 are provided outside the chamber 3. The pipe 82 communicates with and is connected to the chamber 3. The exhaust pump 83 is provided in the pipe 82. For example, the exhaust pump 83 is a vacuum pump. When the decompression unit 81 operates, the exhaust pump 83 discharges gas inside the chamber 3 to the outside of the chamber 3 via the pipe 82. When operation of the decompression unit 81 is stopped, the exhaust pump 83 does not discharge gas inside the chamber 3 to the outside of the chamber 3.

The substrate treatment device 1 has a pressure sensor 89. The pressure sensor 89 is installed inside the chamber 3. The pressure sensor 89 detects the pressure of the gas inside the chamber 3.

The substrate treatment device 1 includes a liquid discharge unit 95. The liquid discharge unit 95 discharges the treatment liquid inside the chamber 3 to the outside of the chamber 3. In the first embodiment, the liquid discharge unit 95 discharges the treatment liquid inside the treatment tank 11 to the outside of the chamber 3. The liquid discharge unit 95 includes a pipe 96 and a drain valve 97. The pipe 96 communicates with and is connected to the treatment tank 11. The pipe 96 has a first end and a second end. The first end of the pipe 96 is positioned inside the chamber 3. The first end of the pipe 96 communicates with and is connected to the treatment tank 11. The first end of the pipe 96 is connected to the discharge port 12b. The pipe 96 extends downward from the treatment tank 11. The pipe 96 penetrates the chamber 3 and extends from the inside of the chamber 3 to the outside of the chamber 3. The second end of the pipe 96 is positioned outside the chamber 3. The second end of the pipe 96 is open to the atmospheric air outside the chamber 3. The drain valve 97 is provided in the pipe 96. The drain valve 97 opens and closes the pipe 96. When the drain valve 97 is opened, the pipe 96 is open to the outside of the chamber 3. When the drain valve 97 is opened, the inside of the treatment tank 11 is open to the outside of the chamber 3 through the pipe 96. When the drain valve 97 is opened, the liquid discharge unit 95 allows the treatment liquid inside the treatment tank 11 to flow out to the outside of the chamber 3 through the pipe 96. When the drain valve 97 is closed, the inside of the treatment tank 11 is isolated from the outside of the chamber 3. When the drain valve 97 is closed, the liquid discharge unit 95 allows the treatment tank 11 to store the treatment liquid.

The pipe 96 is an example of a liquid discharge tube according to the disclosure.

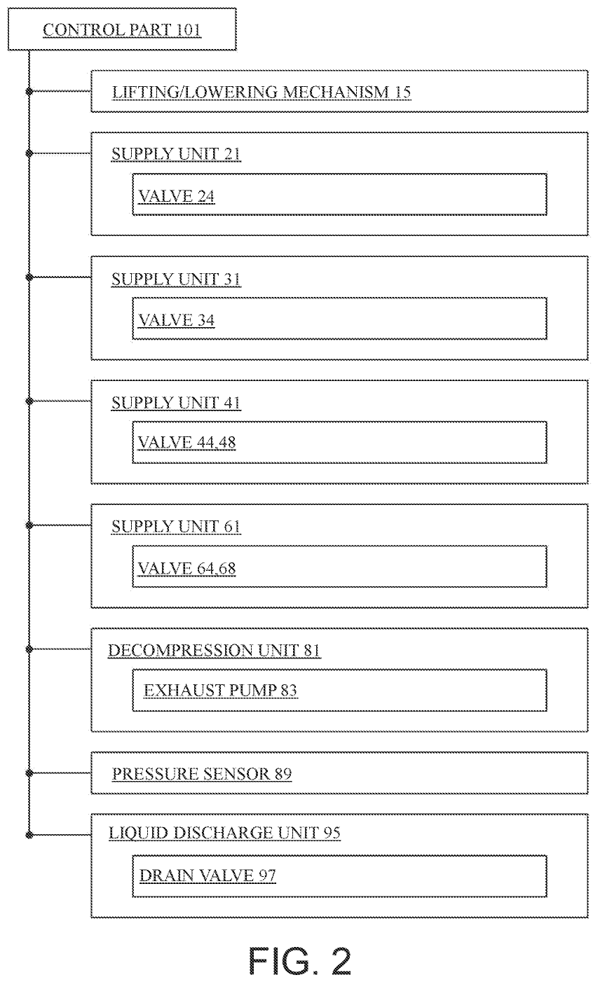

FIG. 2 is a control block diagram of the substrate treatment device 1. The substrate treatment device 1 includes a control part 101. The control part 101 controls each element of the substrate treatment device 1. Specifically, the control part 101 controls the lifting/lowering mechanism 15. The control part 101 controls the supply units 21, 31, 41, and 61. The control part 101 controls the valves 24, 34, 44, 48, 64, and 68. The control part 101 controls the decompression unit 81. The control part 101 controls the exhaust pump 83. The control part 101 acquires detection results of the pressure sensor 89. The control part 101 controls the liquid discharge unit 95. The control part 101 controls the drain valve 97.

The control part 101 is realized by a central processing unit (CPU) executing various kinds of processing, a random-access memory (RAM) serving as a work domain for arithmetic processing, a storage medium such as a hard disk, and the like. The control part 101 has various kinds of information which has been stored in the storage medium in advance. For example, information of the control part 101 is processing information for controlling the substrate treatment device 1. Processing information is also referred to as a processing recipe.

Processing information includes a standard value. The standard value relates to the pressure of the gas inside the chamber 3. The standard value has been set in advance before the substrate treatment method is executed.

<1-2. Examples of Operation of Substrate Treatment Device>

A device (not illustrated) different from the substrate treatment device 1 performs wet etching treatment with respect to the substrate W. For example, wet etching treatment is treatment of supplying an etching liquid to the substrate W. Thereafter, the substrate W is conveyed to the substrate treatment device 1. The chamber 3 is opened. A plurality of substrates W enters the inside of the chamber 3. The holding part 13 receives the plurality of substrates W. In a state in which the chamber 3 accommodates the substrates W, the chamber 3 is closed.

In a state in which the chamber 3 is closed, the substrate treatment device 1 executes the substrate treatment method with respect to the substrate W. The substrate treatment method is a method for simultaneously treating a plurality of substrates W accommodated inside the chamber 3. A specific substrate treatment method will be described below as an example.

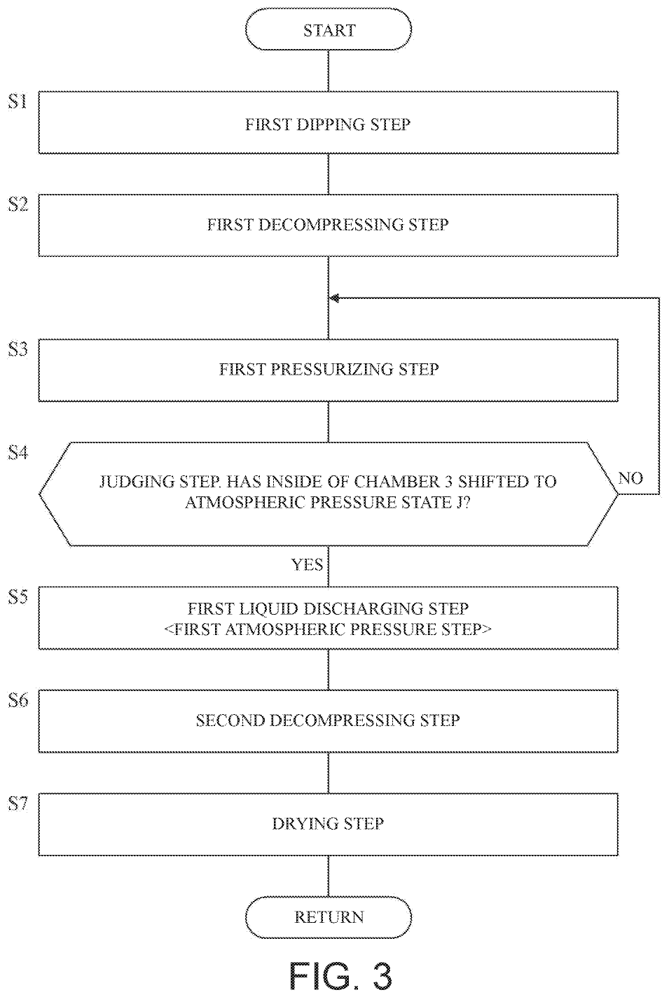

FIG. 3 is a flowchart showing a procedure of the substrate treatment method of the first embodiment. The substrate treatment method includes a first dipping step, a first decompressing step, a first pressurizing step, a judging step, a first liquid discharging step, a second decompressing step, and a drying step. The first dipping step, the first decompressing step, the first pressurizing step, the judging step, the first liquid discharging step, the second decompressing step, and the drying step are executed in this order.

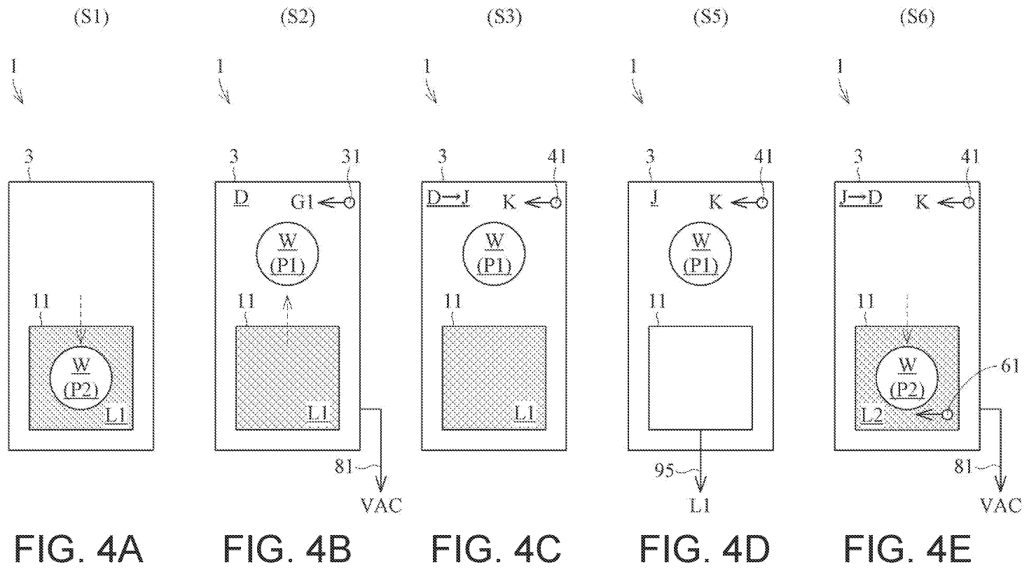

FIG. 4A is a view schematically illustrating the substrate treatment device 1 in the first dipping step. FIG. 4B is a view schematically illustrating the substrate treatment device 1 in the first decompressing step. FIG. 4C is a view schematically illustrating the substrate treatment device 1 in the first pressurizing step. FIG. 4D is a view schematically illustrating the substrate treatment device 1 in the first liquid discharging step. FIG. 4E is a view schematically illustrating the substrate treatment device 1 in the second decompressing step. In each of FIGS. 4A to 4E, the substrate treatment device 1 is simply illustrated. For example, in each of FIGS. 4A to 4E, illustration of the holding part 13 and the lifting/lowering mechanism 15 is omitted. In the following description, it is considered that each element of the substrate treatment device 1 operates in response to control of the control part 101.

Step S1: First Dipping Step

Refer to FIG. 4A. The treatment tank 11 stores a first liquid L1 supplied from the supply unit 61. The lifting/lowering mechanism 15 moves the substrate W to the second position P2. The substrate W is dipped into the first liquid L1 inside the treatment tank 11.

Step S2: First Decompressing Step (First Decompressing Treatment)

Refer to FIG. 4B. The supply unit 31 supplies the treatment gas to the inside of the chamber 3. In this specification, the treatment gas supplied to the chamber 3 in the first decompressing step will be suitably referred to as “a first gas G1”. The decompression unit 81 operates. That is, the decompression unit 81 decompresses the inside of the chamber 3. “VAC” in FIG. 4B indicates that the decompression unit 81 is in operation. The inside of the chamber 3 shifts to a decompressed state D. When the inside of the chamber is in the decompressed state D, the pressure of gas inside the chamber 3 becomes a negative pressure. An atmosphere of the first gas G1 is formed inside the chamber 3. The lifting/lowering mechanism 15 moves the substrate W from the second position P2 to the first position P1. The substrate W is picked up from the first liquid L1 inside the treatment tank 11. In the state D in which the inside of the chamber 3 is decompressed, the supply unit 31 supplies the first gas G1 to the substrate W inside the chamber 3.

The substrate W is exposed to the first gas G1. The gas of the organic solvent included in the first gas G1 is dew-condensed on the surface of the substrate W. That is, the gas of the organic solvent included in the first gas G1 changes to liquid of the organic solvent on the surface of the substrate W. The liquid of the organic solvent derived from the first gas G1 adheres to a part on the substrate W and moistens the substrate W. For this reason, the substrate W does not dry. The organic solvent derived from the first gas G1 removes the first liquid L1 on the substrate W. Since the inside of the chamber 3 is in the decompressed state D, the first liquid L1 is quickly replaced by the organic solvent derived from the first gas G1 on the substrate W. The organic solvent derived from the first gas G1 covers the surface of the substrate W.

Treatment in the first decompressing step is an example of the first decompressing treatment according to the disclosure.

Step S3: First Pressurizing Step (First Pressurizing Treatment)

Refer to FIG. 4C. The substrate W is positioned at the first position P1. The decompression unit 81 stops operation. That is, the decompression unit 81 does not decompress the inside of the chamber 3. The supply unit 41 supplies mixed gas K to the substrate W inside the chamber 3. Specifically, the supply unit 41 generates the mixed gas K, and the generated mixed gas K is supplied to the inside of the chamber 3 by the emission part 42. Accordingly, the inside of the chamber 3 is pressurized from the decompressed state D to an atmospheric pressure state J. Specifically, the inert gas of the mixed gas K quickly pressurizes the inside of the chamber 3 from the decompressed state D to the atmospheric pressure state J. In other words, the inert gas of the mixed gas K quickly raises the pressure of the gas inside the chamber 3. This is because the inert gas is unlikely to be condensed.

The atmosphere inside the chamber 3 includes the organic solvent of the mixed gas K. The substrate W receives the organic solvent of the mixed gas K. Specifically, the liquid of the organic solvent included in the mixed gas K adheres to the substrate W and moistens the substrate W. The liquid of the organic solvent in the mixed gas K covers the surface of the substrate W. For this reason, the substrate W does not dry. The inside of the chamber 3 shifts to the atmospheric pressure state J without causing the substrate W to dry.

The atmospheric pressure state J will be described. The inside of the chamber 3 being in the atmospheric pressure state J denotes that the pressure of the gas inside the chamber 3 is an atmospheric pressure. The atmospheric pressure indicates a range stipulated by two different values instead of one particular value. The atmospheric pressure is higher than the pressure of the gas inside the chamber 3 when the inside of the chamber 3 is in the decompressed state D. The atmospheric pressure is close to the pressure of gas outside the chamber 3. For example, the atmospheric pressure is practically equivalent to the pressure of gas outside the chamber 3. For example, the atmospheric pressure includes a standard atmospheric pressure (1 atm, 101,325 Pa).

In the first pressurizing step, the lifting/lowering mechanism 15 may cause the substrate W to stand still at the first position P1. Alternatively, in the first pressurizing step, the lifting/lowering mechanism 15 may vertically move the substrate W. For example, the lifting/lowering mechanism 15 may vertically move the substrate W near the first position P1. For example, the lifting/lowering mechanism 15 may vertically move the substrate W in the vertical direction Z. Alternatively, the lifting/lowering mechanism 15 may further include a mechanism (not illustrated) for swinging the substrate W. The lifting/lowering mechanism 15 may swing the substrate W by means of the mechanism. When the substrate W is vertically moved or swung, the entire substrate W favorably receives the mixed gas K. When the substrate W is vertically moved or swung, the organic solvent of the mixed gas K adheres more uniformly to the entire surface of the substrate W.

Treatment in the first pressurizing step is an example of the first pressurizing treatment according to the disclosure.

Step S4: Judging Step

The control part 101 judges whether or not the inside of the chamber 3 has shifted to the atmospheric pressure state J based on detection results of the pressure sensor 89. For example, the control part 101 acquires a measurement value of the pressure of the gas inside the chamber 3 on the basis of detection results of the pressure sensor 89. The control part 101 compares the measurement value and a standard value to each other. When the measurement value is smaller than the standard value, the control part 101 does not judge that the inside of the chamber 3 has shifted to the atmospheric pressure state J. When the measurement value is equal to or larger than the standard value, the control part 101 judges that the inside of the chamber 3 has shifted to the atmospheric pressure state J. When the control part 101 does not judge that the inside of the chamber 3 has shifted to the atmospheric pressure state J, the procedure returns to Step S3 and continues the first pressurizing step. When the control part 101 judges that the inside of the chamber 3 has shifted to the atmospheric pressure state J, the first pressurizing step ends, and the procedure proceeds to Step S5.

Step S5: First Liquid Discharging Step <First Atmospheric Pressure Step>

Refer to FIG. 4D. The substrate W is positioned at the first position P1. The supply unit 41 supplies the mixed gas K to the substrate W inside the chamber 3. The decompression unit 81 is at a stop. The inside of the chamber 3 is maintained in the atmospheric pressure state J. The atmosphere inside the chamber 3 includes the organic solvent of the mixed gas K. The liquid discharge unit 95 discharges the first liquid L1 inside the chamber 3 to the outside of the chamber 3. Specifically, the drain valve 97 opens the pipe 96 to the atmospheric air outside the chamber 3. The first liquid L1 stored in the treatment tank 11 is discharged to the outside of the chamber 3 through the pipe 96. In this manner, the first liquid L1 flows from the inside of the chamber 3 to the outside of the chamber 3 through the pipe 96.

The first liquid discharging step of the first embodiment is included in the first atmospheric pressure step of the disclosure.

Step S6: Second Decompressing Step

Refer to FIG. 4E. The supply unit 41 supplies the mixed gas K. The atmosphere inside the chamber 3 includes the organic solvent of the mixed gas K. The drain valve 97 is closed. The supply unit 61 supplies a second liquid L2 to the treatment tank 11. The treatment tank 11 stores the second liquid L2. The lifting/lowering mechanism 15 moves the substrate W from the first position P1 to the second position P2. The substrate W is dipped into the second liquid L2 inside the treatment tank 11. The decompression unit 81 starts operation. The inside of the chamber 3 shifts from the atmospheric pressure state J to the decompressed state D.

Step S7: Drying Step

Illustration of the drying step is omitted. The lifting/lowering mechanism 15 moves the substrate W from the second position P2 to the first position P1. The substrate W is picked up from the second liquid L2 inside the treatment tank 11. The substrate W is positioned at the first position P1. The decompression unit 81 is in operation. The inside of the chamber 3 is maintained in the decompressed state D. The supply unit 21 supplies the inert gas to the substrate W. The inert gas removes the second liquid L2 on the substrate W. The substrate W dries upon removal of the second liquid L2 from the substrate W.

After the drying step, the inside of the chamber 3 is pressurized. For example, the supply unit 21 supplies the inert gas, and the decompression unit 81 stops operation. Accordingly, the inside of the chamber 3 shifts from the decompressed state D to the atmospheric pressure state J.

After the chamber 3 has shifted to the atmospheric pressure state J, the chamber 3 is open. Further, the substrate W inside the chamber 3 is carried out to the outside of the chamber 3.

<1-3. Effects of First Embodiment>

The substrate treatment method includes the first decompressing step and the first pressurizing step. In the first decompressing step, the inside of the chamber 3 is in a decompressed state, and the first gas G1 is supplied to the substrate W inside the chamber 3. The first gas G1 includes the organic solvent. For this reason, the substrate W does not dry in the first decompressing step. The first pressurizing step is executed after the first decompressing step. In the first pressurizing step, the mixed gas K is supplied to the substrate W inside the chamber 3, and the inside of the chamber 3 is pressurized from the decompressed state D to the atmospheric pressure state J. The mixed gas K includes an organic solvent and inert gas. For this reason, in the first pressurizing step, the inside of the chamber 3 can be appropriately pressurized from the decompressed state D to the atmospheric pressure state J. Specifically, in the first pressurizing step, the inside of the chamber 3 can be quickly pressurized from the decompressed state D to the atmospheric pressure state J without causing the substrate W inside the chamber 3 to dry. In the first pressurizing step, the substrate W does not dry.

The substrate treatment method includes the first liquid discharging step. The first liquid discharging step is executed after the first pressurizing step. In the first liquid discharging step, the inside of the chamber 3 is maintained in the atmospheric pressure state J, and the liquid discharge treatment is performed. When the inside of the chamber 3 is in the atmospheric pressure state J, the pressure of the gas inside the chamber 3 is close to the pressure of gas outside the chamber 3. For this reason, it is easy to perform the liquid discharge treatment in the first liquid discharging step. Thus, the first liquid discharging step is favorably executed.

The mixed gas K includes liquid of the organic solvent. The liquid of the organic solvent in the mixed gas K adheres to the surface of the substrate W and favorably moistens the substrate W. Thus, the mixed gas K favorably prevents the substrate W from drying.

In the first pressurizing step, the mixed gas K is generated, and the generated mixed gas K is supplied to the inside of the chamber 3 by the emission part 42. In other words, in the first pressurizing step, the mixed gas K is not generated inside the chamber 3. In the first pressurizing step, the inert gas and the organic solvent are not individually supplied to the chamber 3. For this reason, in the first pressurizing step, the inert gas supplied to the inside of the chamber 3 is accompanied by the organic solvent. In the first pressurizing step, the inert gas supplied to the inside of the chamber 3 is not separated from the organic solvent. For this reason, the substrate W does not receive only the inert gas. The substrate W receives the organic solvent together with the inert gas. Thus, in the first pressurizing step, the substrate W is more reliably prevented from drying. For example, in the first pressurizing step, the substrate W is favorably prevented from having a dry portion. For example, in the first pressurizing step, not only drying of the entire substrate W but partial drying of the substrate W is also favorably prevented. For example, in the first pressurizing step, not only drying of the entire substrate W but local drying of the substrate W is also favorably prevented.

The substrate treatment method further includes the first dipping step. The first dipping step is executed before the first decompressing step. In the first dipping step, the substrate W is dipped into the first liquid L1 stored in the treatment tank 11. The treatment tank 11 is installed inside the chamber 3. In the first liquid discharging step, the first liquid L1 is discharged to the outside of the chamber 3. As described above, in the first liquid discharging step, the inside of the chamber 3 is maintained in the atmospheric pressure state J. Thus, in the first liquid discharging step, it is easy to discharge the first liquid L1 inside the chamber 3 to the outside of the chamber 3.

In the first liquid discharging step, the pipe 96 is open to the atmospheric air outside the chamber 3. The pipe 96 communicates with and is connected to the treatment tank 11. As described above, in the first liquid discharging step, the inside of the chamber 3 is in the atmospheric pressure state J. For this reason, in the first liquid discharging step, due to the dead weight of the first liquid L1, the first liquid L1 flows from the inside of the chamber 3 to the outside of the chamber 3 through the pipe 96. In the first liquid discharging step, the first liquid L1 naturally flows from the inside of the chamber 3 to the outside of the chamber 3 through the pipe 96. In the first liquid discharging step, it is not necessary to forcibly send the first liquid L1 from the inside of the chamber 3 to the outside of the chamber 3. Thus, in the first liquid discharging step, it is easy to discharge the first liquid L1 inside the chamber 3 to the outside of the chamber 3 through the pipe 96.

The substrate treatment method includes the second decompressing step. In the second decompressing step, the inside of the chamber 3 is in a decompressed state, and the substrate W is dipped into the second liquid L2 stored in the treatment tank 11. As described above, the substrate W does not dry in the first pressurizing step. Moreover, in the first liquid discharging step, the inside of the chamber 3 is maintained in the atmospheric pressure state J. For this reason, the substrate W is unlikely to dry in the first liquid discharging step. The second decompressing step is executed after the first liquid discharging step. Thus, the substrate W is unlikely to dry from the first pressurizing step to the first liquid discharging step. After the first decompressing step and before the second decompressing step, the substrate W is unlikely to dry. Therefore, in the second decompressing step, it is easy to perform treatment of the substrate W with appropriate quality.

The atmosphere inside the chamber 3 includes an organic solvent until the substrate W is dipped into the second liquid L2 in the treatment tank 11 after the first pressurizing step. For this reason, the organic solvent included in the atmosphere inside the chamber 3 moistens the substrate W until the substrate W is dipped into the second liquid L2 after the first pressurizing step. Thus, the substrate W does not dry from the first pressurizing step to the second decompressing step. After the first decompressing step and before the second decompressing step, the substrate W does not dry. Therefore, in the second decompressing step, the substrate W is treated with appropriate quality.

The mixed gas K is further supplied to the substrate W inside the chamber 3 until the substrate W is dipped into the second liquid L2 in the treatment tank 11 after the first pressurizing step. For this reason, the atmosphere inside the chamber 3 favorably includes the organic solvent until the substrate W is dipped into the second liquid L2 inside the treatment tank 11 after the first pressurizing step.

The substrate treatment device 1 includes the chamber 3, the supply units 31 and 41, the decompression unit 81, and the control part 101. The chamber 3 accommodates a plurality of substrates W. The supply unit 31 supplies the first gas G1 to the substrate W inside the chamber 3. The supply unit 41 supplies the mixed gas K to the substrate W inside the chamber 3. The decompression unit 81 decompresses the inside of the chamber 3. The control part 101 controls the supply units 31 and 41 and the decompression unit 81 to execute the first decompressing treatment and the first pressurizing treatment. In the first decompressing treatment, the decompression unit 81 decompresses the inside of the chamber 3, and the supply unit 31 supplies the first gas G1 to the substrate W. The first pressurizing treatment is executed after the first decompressing treatment. In the first pressurizing treatment, the decompression unit 81 does not decompress the inside of the chamber 3, and the supply unit 41 supplies the mixed gas K to the substrate W. For this reason, in the first pressurizing treatment, the substrate W does not dry. In the first pressurizing treatment, the inside of the chamber 3 is quickly pressurized from the decompressed state D to the atmospheric pressure state J without causing the substrate W to dry. Thus, in the substrate treatment device 1, the inside of the chamber 3 can be appropriately pressurized from the decompressed state D to the atmospheric pressure state J. Therefore, after the first pressurizing treatment, substrate treatment in the second decompressing step is favorably executed.

### 2. Second Embodiment

A second embodiment will be described with reference to the drawings. The same reference signs are applied to the same constituents as the first embodiment, and therefore detailed description thereof will be omitted.

<2-1. Overview of Substrate Treatment Device>

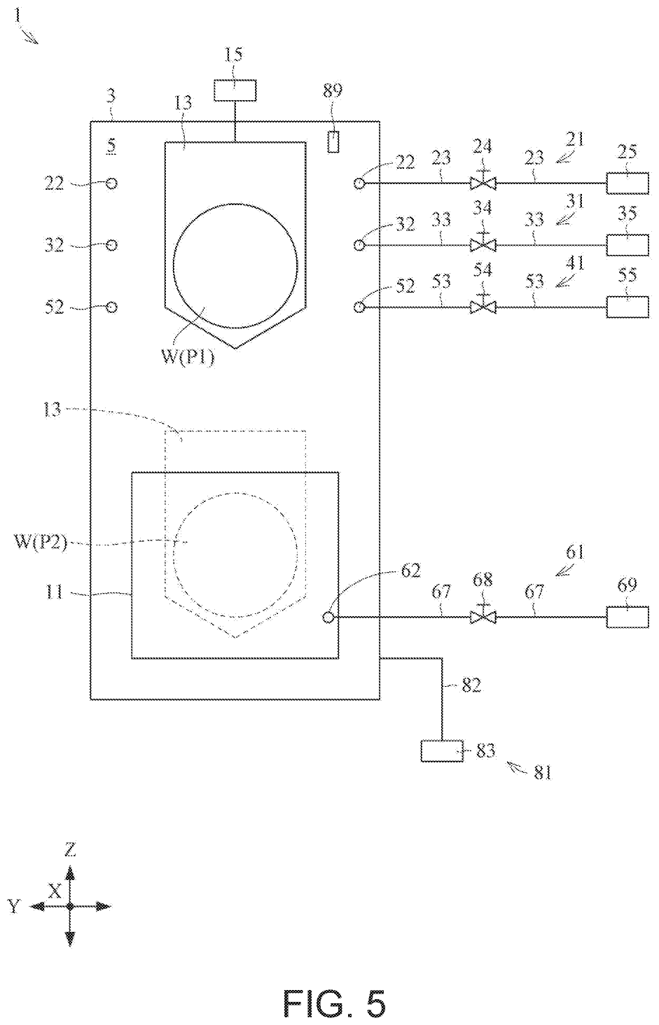

FIG. 5 is a front view illustrating the inside of the substrate treatment device 1 of the second embodiment.

As described above, the mixed gas K includes an organic solvent and inert gas. In the second embodiment, the mixed gas K includes gas of the organic solvent. That is, the organic solvent of the mixed gas K is in a gas phase. For example, gas of the organic solvent in the mixed gas K is vapor of the organic solvent. For example, the mixed gas K includes vapor of the organic solvent and inert gas. For example, the organic solvent of the mixed gas K is isopropyl alcohol. For example, the inert gas of the mixed gas K is nitrogen gas.

A structure of the supply unit 41 will be described as an example. The supply unit 41 has an emission part 52. The emission part 52 is installed inside the chamber 3. The emission part 52 is disposed at a position higher than the treatment tank 11. The emission part 52 is disposed on both sides of the substrate W positioned at the first position P1 in the direction Y. The emission part 52 emits the mixed gas K to the inside of the chamber 3. For example, the emission part 52 has a structure similar to the structure of the emission part 22.

The emission part 52 is an example of the first emission part according to the disclosure.

The supply unit 41 includes a pipe 53 and a valve 54. The pipe 53 is connected to the emission part 52. The pipe 53 is also connected to a supply source 55. The supply source 55 stores the mixed gas K. The valve 54 is provided in the pipe 53. The valve 54 controls emission of the mixed gas K performed by the emission part 52.

The supply source 55 may further generate the mixed gas K. Although illustration is omitted, for example, the supply source 55 includes a tank and a heater. The tank communicates with and is connected to the pipe 53. The tank stores liquid of the organic solvent. The tank further stores inert gas. The heater warms liquid of the organic solvent inside the tank. Inside the tank, liquid of the organic solvent is vaporized and becomes vapor of the organic solvent. Inside the tank, vapor of the organic solvent and the inert gas are mixed and become the mixed gas K. That is, the mixed gas K is generated inside the tank.

In the second embodiment, the supply unit 61 does not supply the first liquid L1. For this reason, in the second embodiment, the supply unit 61 does not include the pipe 63, the valve 64, and the supply source 65.

Although illustration is omitted, the control part 101 controls the valve 54.

<2-2. Examples of Operation of Substrate Treatment Device>

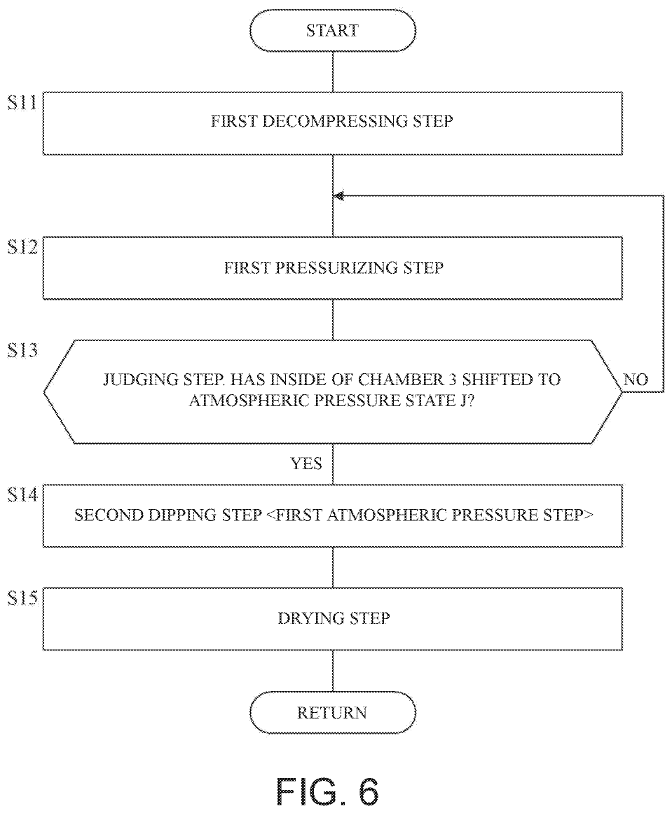

FIG. 6 is a flowchart showing a procedure of the substrate treatment method of the second embodiment. The substrate treatment method includes Steps S11 to S15. The substrate treatment method includes the first decompressing step, the first pressurizing step, the judging step, a second dipping step, and the drying step. The first decompressing step, the first pressurizing step, the judging step, the second dipping step, and the drying step are executed in this order.

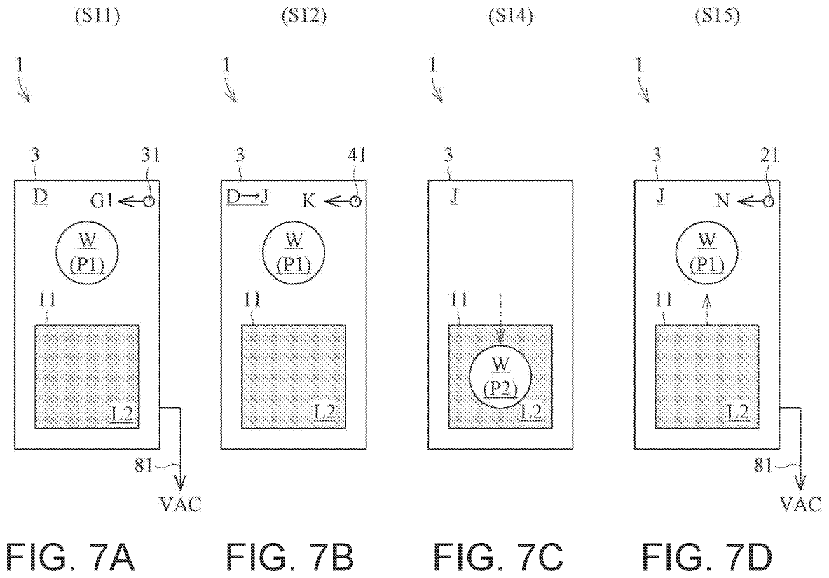

FIG. 7A is a view schematically illustrating the substrate treatment device 1 in the first decompressing step. FIG. 7B is a view schematically illustrating the substrate treatment device 1 in the first pressurizing step. FIG. 7C is a view schematically illustrating the substrate treatment device 1 in the second dipping step. FIG. 7D is a view schematically illustrating the substrate treatment device 1 in the drying step. In each of FIGS. 7A to 7D, the substrate treatment device 1 is simply illustrated.

Step S11: First Decompressing Step (First Decompressing Treatment)

Refer to FIG. 7A. The substrate W is positioned at the first position P1. The decompression unit 81 decompresses the inside of the chamber 3. The inside of the chamber 3 shifts to the decompressed state D. In the state D in which the inside of the chamber 3 is decompressed, the supply unit 31 supplies the first gas G1 to the substrate W inside the chamber 3. The substrate W receives the organic solvent derived from the first gas G1. The substrate W does not dry.

Treatment in the first decompressing step is an example of the first decompressing treatment according to the disclosure.

Step S12: First Pressurizing Step (First Pressurizing Treatment)

Refer to FIG. 7B. The first pressurizing step of the second embodiment is practically the same as the first pressurizing step of the first embodiment. In short, the substrate W is positioned at the first position P1. The decompression unit 81 stops operation and does not decompress the inside of the chamber 3. The supply unit 41 supplies the mixed gas K to the substrate W inside the chamber 3. Specifically, the supply unit 41 generates the mixed gas K and supplies the generated mixed gas K to the inside of the chamber 3 by the emission part 52. Accordingly, the inside of the chamber 3 is pressurized from the decompressed state D to the atmospheric pressure state J.

The atmosphere inside the chamber 3 includes the organic solvent of the mixed gas K. The substrate W receives the organic solvent of the mixed gas K. Specifically, the gas of the organic solvent included in the mixed gas K is dew-condensed on the surface of the substrate W. That is, gas of the organic solvent in the mixed gas K changes to liquid of the organic solvent on the surface of the substrate W. The liquid of the organic solvent derived from the mixed gas K adheres to a part on the substrate W and moistens the substrate W. The liquid of the organic solvent derived from the mixed gas K covers the surface of the substrate W. For this reason, the substrate W does not dry. The inside of the chamber 3 shifts to the atmospheric pressure state J without causing the substrate W to dry.

In the first pressurizing step, the lifting/lowering mechanism 15 may cause the substrate W to stand still at the first position P1. Alternatively, in the first pressurizing step, the lifting/lowering mechanism 15 may vertically move the substrate W. For example, the lifting/lowering mechanism 15 may vertically move the substrate W near the first position P1. For example, the lifting/lowering mechanism 15 may vertically move the substrate W in the vertical direction Z. Alternatively, the lifting/lowering mechanism 15 may further include a mechanism (not illustrated) for swinging the substrate W. The lifting/lowering mechanism 15 may swing the substrate W by means of the mechanism. When the substrate W is vertically moved or swung, the entire substrate W favorably receives the mixed gas K. When the substrate W is vertically moved or swung, the organic solvent derived from the mixed gas K adheres more uniformly to the entire surface of the substrate W.

Treatment in the first pressurizing step is an example of the first pressurizing treatment according to the disclosure.

Step S13: Judging Step

The control part 101 judges whether or not the inside of the chamber 3 has shifted to the atmospheric pressure state J based on detection results of the pressure sensor 89. When the control part 101 does not judge that the inside of the chamber 3 has shifted to the atmospheric pressure state J, the procedure returns to Step S12 and continues the first pressurizing step. When the control part 101 judges that the inside of the chamber 3 has shifted to the atmospheric pressure state J, the first pressurizing step ends, and the procedure proceeds to Step S14.

Step S14: Second Dipping Step <First Atmospheric Pressure Step>

Refer to FIG. 7C. The decompression unit 81 is at a stop. The inside of the chamber 3 is maintained in the atmospheric pressure state J. The atmosphere inside the chamber 3 includes the organic solvent of the mixed gas K. The supply unit 41 stops supplying of the mixed gas K. The treatment tank 11 stores the second liquid L2 supplied from the supply unit 61. The lifting/lowering mechanism 15 moves the substrate W from the first position P1 to the second position P2. The substrate W is dipped into the second liquid L2 inside the treatment tank 11.

The second dipping step of the second embodiment is included in the first atmospheric pressure step of the disclosure.

Step S15: Drying Step

Refer to FIG. 7D. The lifting/lowering mechanism 15 moves the substrate W from the second position P2 to the first position P1. The substrate W is picked up from the second liquid L2 inside the treatment tank 11. The substrate W is positioned at the first position P1. The decompression unit 81 starts operation and decompresses the inside of the chamber 3. The inside of the chamber 3 shifts from the atmospheric pressure state J to the decompressed state D. The supply unit 21 supplies inert gas N to the substrate W. The inert gas removes the second liquid L2 on the substrate W. The substrate W dries.

<2-3. Effects of Second Embodiment>

According to the second embodiment, effects similar to those of the first embodiment are exhibited. For example, the inside of the chamber 3 can be appropriately pressurized from the decompressed state D to the atmospheric pressure state J even by the substrate treatment method of the second embodiment. Moreover, according to the second embodiment, the following effects are exhibited.

The mixed gas K includes gas of the organic solvent. Gas of the organic solvent in the mixed gas K is dew-condensed on the surface of the substrate W and changes to liquid of the organic solvent on the surface of the substrate W. The organic solvent derived from the mixed gas K favorably moistens the substrate W. Thus, the mixed gas K favorably prevents the substrate W from drying.

The substrate treatment method includes the second dipping step. In the second dipping step, the inside of the chamber 3 is maintained in the atmospheric pressure state J, and the substrate W is dipped into the second liquid L2 stored in the treatment tank 11. The second dipping step is executed after the first pressurizing step. The substrate does not dry in the first pressurizing step. For this reason, after the first decompressing step and before the second dipping step, the substrate W does not dry. Thus, in the second dipping step, the substrate W is treated with appropriate quality.

The atmosphere inside the chamber 3 includes the organic solvent until the substrate W is dipped into the second liquid L2 in the treatment tank 11 after the first pressurizing step. For this reason, the organic solvent included in the atmosphere inside the chamber 3 moistens the substrate W until the substrate W is dipped into the second liquid L2 in the treatment tank 11 after the first pressurizing step. Thus, from the first pressurizing step to the second dipping step, the substrate W does not dry. After the first decompressing step and before the second dipping step, the substrate W does not dry. Therefore, in the second dipping step, the substrate W is treated with appropriate quality.

In the second dipping step of the second embodiment, although the mixed gas K is not supplied to the inside of the chamber 3, the atmosphere inside the chamber 3 includes the organic solvent. The reason is as follows. In the first pressurizing step, the atmosphere of the mixed gas K is formed inside the chamber 3. In the second dipping step, the inside of the chamber 3 is not decompressed. For this reason, in the second dipping step, the atmosphere of the mixed gas K remains inside the chamber 3. Thus, in the second dipping step as well, the atmosphere of the chamber 3 includes the organic solvent of the mixed gas K.

### 3. Third Embodiment

A third embodiment will be described with reference to the drawings. The same reference signs are applied to the same constituents as the first embodiment, and therefore detailed description thereof will be omitted.

<3-1. Overview of Substrate Treatment Device>

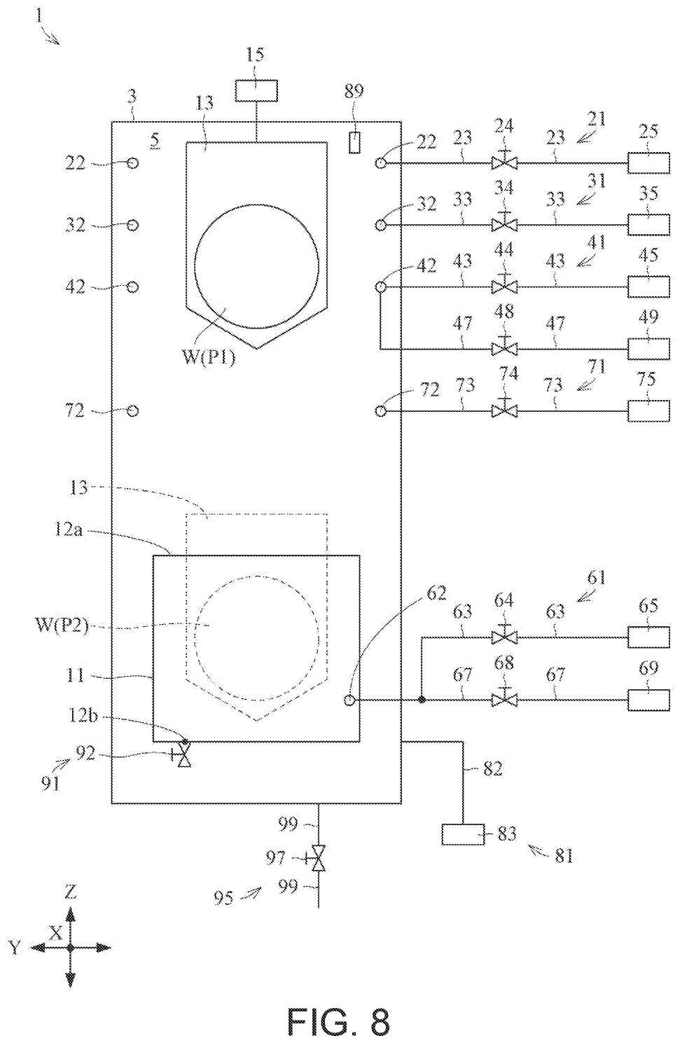

FIG. 8 is a front view illustrating the inside of the substrate treatment device 1 of the third embodiment. The substrate treatment device 1 includes a supply unit 71. The supply unit 71 supplies a water-repellent agent to the chamber 3. When the substrate W is positioned at the first position P1, the supply unit 71 supplies the water-repellent agent to the substrate W.

The water-repellent agent supplied by the supply unit 71 will be described. The water-repellent agent causes the surface of the substrate W to be water repellent. The water-repellent agent modifies the surface of the substrate W to be water repellent. The water-repellent agent increases a contact angle between the surface of the substrate W and water. The water-repellent agent forms a water-repellent film on the surface of the substrate W. The surface of the substrate W is coated with the water-repellent agent. The water-repellent agent is also referred to as an interfacial modifier. The water-repellent agent is also referred to as a hydrophobizing agent.

For example, the water-repellent agent includes at least any of a silicon-based water-repellent agent and a metal-based water-repellent agent. The silicon-based water-repellent agent causes silicon to be water repellent. The silicon-based water-repellent agent causes a compound including silicon to be water repellent. For example, the silicon-based water-repellent agent is a silane coupling agent. For example, a silane coupling agent includes at least one of hexamethyldisilazane (HMDS), tetramethylsilane (TMS), fluorinated alkylchlorosilane, alkyl disilazane, and a non-chloro-based water-repellent agent. For example, a non-chloro-based water-repellent agent includes at least one of dimethylsilyldimethylamine, dimethylsilyldiethylamine, hexamethyldisilazane, tetramethyldisilazane, bis(dimethylamino)dimethylsilane, N,N-dimethylaminotrimethylsilane, N-(trimethylsilyl)dimethylamine, and an organosilane compound. The metal-based water-repellent agent causes a metal to be water repellent. The metal-based water-repellent agent causes a compound including a metal to be water repellent. For example, the metal-based water-repellent agent includes at least one of amine having a hydrophobic group, and an organic silicon compound.

The water-repellent agent may further include a solvent. For example, a solvent may also be obtained by diluting at least any of a silicon-based water-repellent agent and a metal-based water-repellent agent. It is preferable that the solvent have phase solubility with respect to an organic solvent. For example, a solvent includes at least any of isopropyl alcohol (IPA) and propylene glycol monomethyl ether acetate (PGMEA).

The water-repellent agent includes at least any of gas of the water-repellent agent and liquid of the water-repellent agent. The supply unit 71 supplies at least any of gas of the water-repellent agent and liquid of the water-repellent agent. For example, the gas of the water-repellent agent is vapor of the water-repellent agent.

A structure of the supply unit 71 will be described as an example. The supply unit 71 has an emission part 72. The emission part 72 is installed inside the chamber 3. The emission part 72 is disposed at a position higher than the treatment tank 11. The emission part 72 is disposed on both sides of the substrate W positioned at the first position P1 in the direction Y. The emission part 72 emits the water-repellent agent to the inside of the chamber 3. For example, the emission part 72 has a structure similar to the structure of the emission part 22.

The supply unit 71 includes a pipe 73 and a valve 74. The pipe 73 is connected to the emission part 72. The pipe 73 is also connected to a supply source 75. The supply source 75 stores the water-repellent agent. The valve 74 is provided in the pipe 73. The valve 74 controls emission of the water-repellent agent by the emission part 72.

The substrate treatment device 1 includes a dumping unit 91. The dumping unit 91 releases the treatment liquid inside the treatment tank 11. The chamber 3 receives the treatment liquid released from the treatment tank 11. The treatment liquid released from the treatment tank 11 is accumulated in a bottom part of the chamber 3. The dumping unit 91 includes a dumping valve 92. The dumping valve 92 is installed inside the chamber 3. The dumping valve 92 is attached to the bottom part of the treatment tank 11. The dumping valve 92 communicates with and is connected to the discharge port 12b. When the dumping valve 92 is opened, the dumping unit 91 allows the treatment liquid to flow down from the inside of the treatment tank 11 to the outside of the treatment tank 11 through the dumping valve 92. When the dumping valve 92 is closed, the dumping unit 91 allows the treatment tank 11 to store the treatment liquid.

The liquid discharge unit 95 discharges the treatment liquid inside the chamber 3 to the outside of the chamber 3. In the third embodiment, the liquid discharge unit 95 discharges the treatment liquid accumulated in the bottom part of the chamber 3 to the outside of the chamber 3. The liquid discharge unit 95 includes a pipe 99 in addition to the drain valve 97. The pipe 99 is provided outside the chamber 3. The pipe 99 communicates with and is connected to the chamber 3. The pipe 99 has a first end and a second end. The first end of the pipe 99 communicates with and is connected to the chamber 3. The first end of the pipe 99 is connected to the bottom part of the chamber 3. The pipe 99 extends downward from the chamber 3. The second end of the pipe 99 is open to the atmospheric air outside the chamber 3. The drain valve 97 is provided in the pipe 99. The drain valve 97 opens and closes the pipe 99. When the drain valve 97 is opened, the pipe 99 is open to the outside of the chamber 3. When the drain valve 97 is opened, the inside of the chamber 3 is open to the outside of the chamber 3 through the pipe 99. When the drain valve 97 is opened, the liquid discharge unit 95 allows the treatment liquid inside the chamber 3 to flow to the outside of the chamber 3 through the pipe 99. When the drain valve 97 is closed, the inside of the chamber 3 is isolated from the outside of the chamber 3. When the drain valve 97 is closed, the liquid discharge unit 95 allows the inside of the chamber 3 to shift to the decompressed state D.

The pipe 99 is an example of the liquid discharge tube according to the disclosure.

Although illustration is omitted, the control part 101 controls the supply unit 71. The control part 101 controls the valve 74. The control part 101 controls the dumping unit 91. The control part 101 controls the dumping valve 92.

<3-2. Examples of Operation of Substrate Treatment Device>

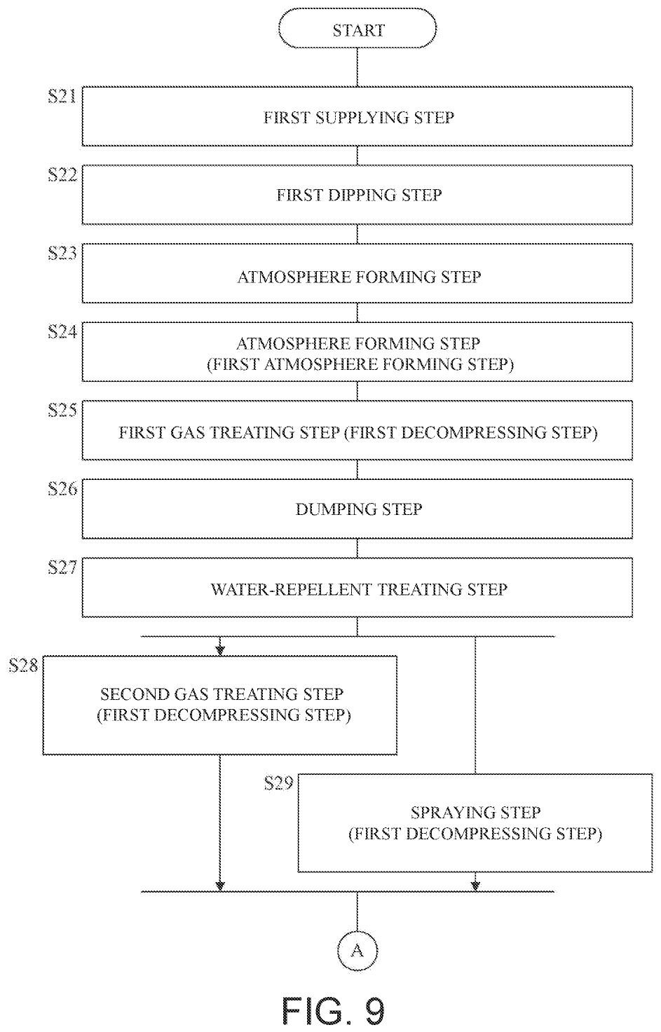

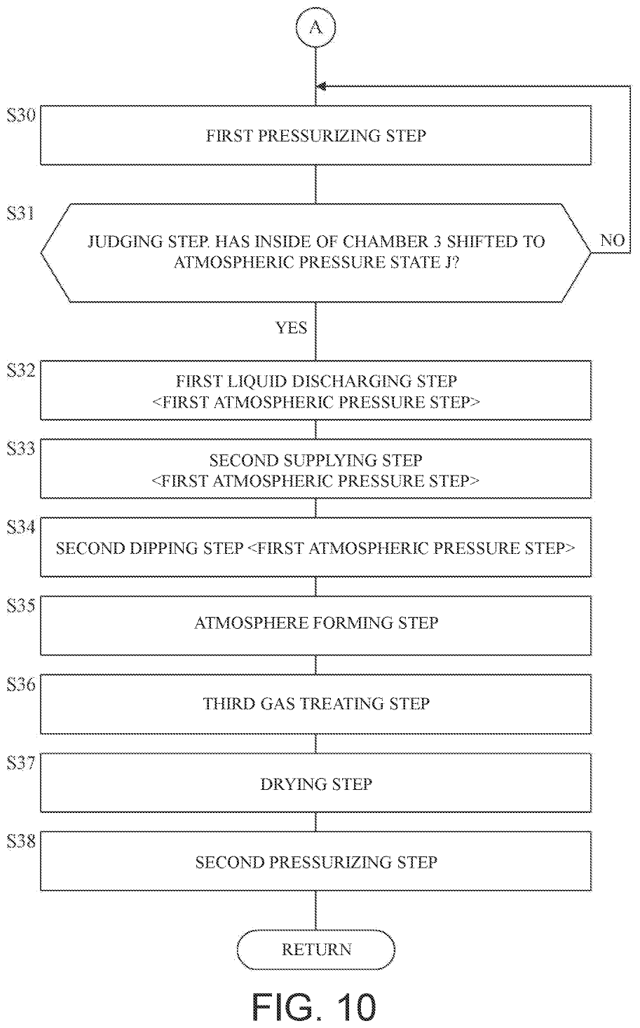

Each of FIGS. 9 and 10 is a flowchart showing a procedure of the substrate treatment method of the third embodiment. The substrate treatment method includes Steps S21 to S38. Steps S21 to S27 are executed in this order. Steps S28 to S29 are executed after Step S27 and before Step S30. Steps S30 to S38 are executed in this order.

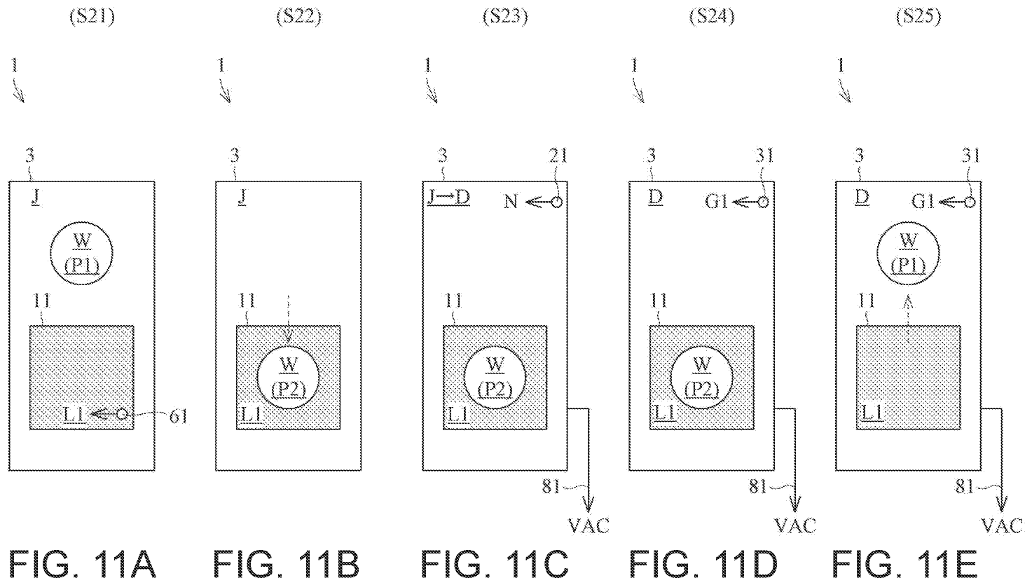

Each of FIGS. 11A to 11E, 12A to 12E, 13A to 13E, and 14A to 14B is a view schematically illustrating the substrate treatment device 1 in Steps S21 to S30 and S32 to S38. In each of FIGS. 11A to 11E and the like, the substrate treatment device 1 is simply illustrated.

Step S21: First Supplying Step

Refer to FIG. 11A. The substrate W is positioned at the first position P1. The inside of the chamber 3 is in the atmospheric pressure state J. The supply unit 61 supplies the first liquid L1 to the treatment tank 11. The dumping valve 92 is closed. The treatment tank 11 stores the first liquid L1. Thereafter, the supply unit 61 stops supplying of the first liquid L1.

Step S22: First Dipping Step

Refer to FIG. 11B. The inside of the chamber 3 is in the atmospheric pressure state J. The lifting/lowering mechanism 15 moves the substrate W from the first position P1 to the second position P2. The substrate W is dipped into the first liquid L1 inside the treatment tank 11.

Step S23: Atmosphere Forming Step

Refer to FIG. 11C. The substrate W is positioned at the second position P2 and is dipped into the first liquid L1 inside the treatment tank 11. The supply unit 21 supplies the inert gas N to the inside of the chamber 3. The decompression unit 81 starts operation. The drain valve 97 is closed. The inside of the chamber 3 shifts from the atmospheric pressure state J to the decompressed state D. In a state in which the substrate W is dipped into the first liquid L1, an atmosphere of the inert gas N is formed inside the chamber 3.

Step S24: Atmosphere Forming Step (First Atmosphere Forming Step)

Refer to FIG. 11D. The substrate W is positioned at the second position P2 and is dipped into the first liquid L1 inside the treatment tank 11. The decompression unit 81 is in operation. The inside of the chamber 3 is maintained in the decompressed state D. The supply unit 21 stops supplying of the inert gas N. The supply unit 31 supplies the first gas G1 to the inside of the chamber 3. In a state in which the substrate W is dipped into the first liquid L1, an atmosphere of the first gas G1 is formed inside the chamber 3.

The atmosphere forming step of Step S24 is an example of the first atmosphere forming step according to the disclosure.

Step S25: First Gas Treating Step (First Decompressing Step)

Refer to FIG. 11E. The decompression unit 81 is in operation. That is, the decompression unit 81 decompresses the inside of the chamber 3. The inside of the chamber 3 is maintained in the decompressed state D. The supply unit 31 supplies the first gas G1 to the inside of the chamber 3. The lifting/lowering mechanism 15 moves the substrate W from the second position P2 to the first position P1. In the state D in which the inside of the chamber 3 is decompressed, the substrate W is picked up from the first liquid L1 inside the treatment tank 11 to above the treatment tank 11. The supply unit 31 supplies the first gas G1 to the substrate W. The substrate W receives the organic solvent derived from the first gas G1. The organic solvent derived from the first gas G1 removes the first liquid L1 on the substrate W. The liquid of the organic solvent derived from the first gas G1 covers the surface of the substrate W.

The first gas treating step is an example of the first decompressing step according to the disclosure. Treatment in the first gas treating step is an example of the first decompressing treatment according to the disclosure.

Step S26: Dumping Step

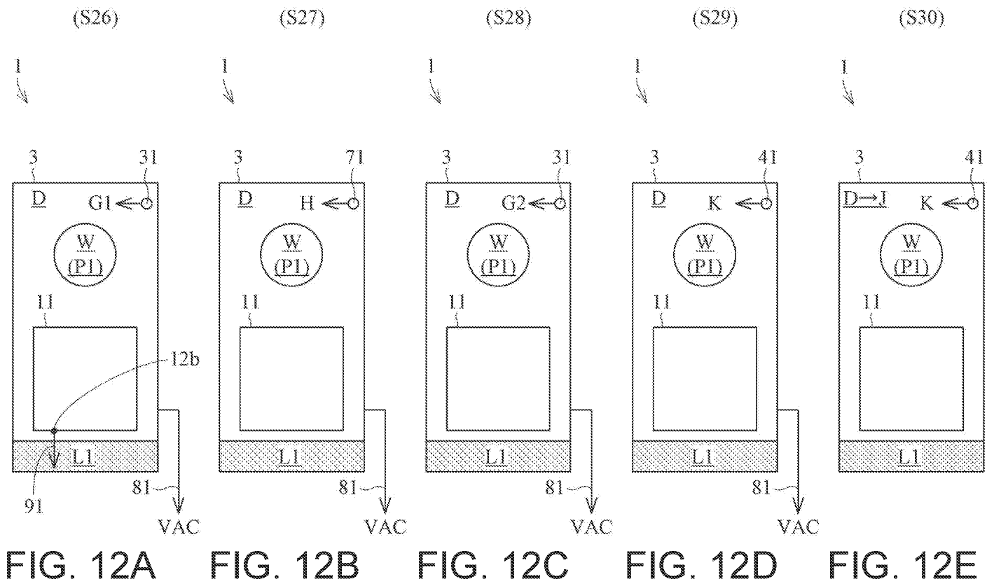

Refer to FIG. 12A. The substrate W is positioned at the first position P1. The supply unit 31 supplies the first gas G1 to the substrate W inside the chamber 3. The decompression unit 81 is in operation. The inside of the chamber 3 is maintained in the decompressed state D. The dumping valve 92 is opened. The dumping unit 91 releases the first liquid L1 from the treatment tank 11. The drain valve 97 is closed. The first liquid L1 is accumulated in the bottom part of the chamber 3.

Step S27: Water-Repellency Treatment Step

Refer to FIG. 12B. The substrate W is positioned at the first position P1. The decompression unit 81 is in operation. The inside of the chamber 3 is maintained in the decompressed state D. The supply unit 31 stops supplying of the first gas G1. The supply unit 71 supplies a water-repellent agent H to the substrate W inside the chamber 3. The water-repellent agent H adheres to the substrate W. On the substrate W, the organic solvent derived from the first gas G1 is replaced by the water-repellent agent H. The water-repellent agent H covers the surface of the substrate W. The water-repellent agent H causes the substrate W to be water repellent.

A portion of the water-repellent agent H on the substrate W changes to a water-repellent film. The water-repellent film is formed on the surface of the substrate W. Other portions of the water-repellent agent H on the substrate W become an unreacted portion of the water-repellent agent H. The unreacted portion of the water-repellent agent H does not react and remains on the substrate W as it is. The unreacted portion of the water-repellent agent H is also referred to as a residue of the water-repellent agent H or a surplus of the water-repellent agent H. Moreover, another portion of the water-repellent agent H on the substrate W may change to particles. The particles are also referred to as foreign matters. For example, particles derived from the water-repellent agent H are generated when the water-repellent agent H comes into contact with the organic solvent. For example, particles derived from the water-repellent agent H are generated when the water-repellent agent H comes into contact with the substrate W. Moreover, the unreacted portion of the water-repellent agent H may become particles derived from the water-repellent agent H.

Thereafter, the supply unit 71 stops supplying of the water-repellent agent H.

Step S28: Second Gas Treating Step (First Decompressing Step/First Decompressing Treatment)

Refer to FIG. 12C. The substrate W is positioned at the first position P1. The decompression unit 81 is in operation. The inside of the chamber 3 is maintained in the decompressed state D. The supply unit 31 supplies the treatment gas to the substrate W inside the chamber 3. In this specification, the treatment gas supplied to the chamber 3 in the second gas treating step will be suitably referred to as “a second gas G2”. The substrate W receives the organic solvent derived from the second gas G2. The organic solvent derived from the second gas G2 removes the unreacted water-repellent agent H on the substrate W. The organic solvent derived from the second gas G2 removes particles derived from the water-repellent agent H on the substrate W. The liquid of the organic solvent derived from the second gas G2 covers the surface of the substrate W. Thereafter, the supply unit 31 stops supplying of the second gas G2.

Step S29: Spraying Step (First Decompressing Step/First Decompressing Treatment)

Refer to FIG. 12D. The substrate W is positioned at the first position P1. The decompression unit 81 is in operation. The inside of the chamber 3 is maintained in the decompressed state D. The supply unit 41 supplies the mixed gas K to the substrate W inside the chamber 3. The substrate W receives the organic solvent of the mixed gas K. The organic solvent of the mixed gas K removes the unreacted water-repellent agent H on the substrate W. The organic solvent of the mixed gas K removes particles derived from the water-repellent agent H on the substrate W. The liquid of the organic solvent derived from the mixed gas K covers the surface of the substrate W.

In the spraying step, the lifting/lowering mechanism 15 may cause the substrate W to stand still at the first position P1. Alternatively, in the spraying step, the lifting/lowering mechanism 15 may vertically move the substrate W. For example, the lifting/lowering mechanism 15 may vertically move the substrate W near the first position P1. For example, the lifting/lowering mechanism 15 may vertically move the substrate W in the vertical direction Z. Alternatively, the lifting/lowering mechanism 15 may further include a mechanism (not illustrated) for swinging the substrate W. The lifting/lowering mechanism 15 may swing the substrate W by means of the mechanism. When the substrate W is vertically moved or swung, the entire substrate W favorably receives the mixed gas K. When the substrate W is vertically moved or swung, the organic solvent of the mixed gas K adheres more uniformly to the entire surface of the substrate W.

Here, the second gas treating step and the spraying step may be executed in an arbitrary order. For example, the spraying step may be executed before the second gas treating step. For example, the spraying step may be executed after the second gas treating step. For example, the spraying step may be simultaneously executed with the second gas treating step.

The second gas treating step is an example of the first decompressing step according to the disclosure. Treatment in the second gas treating step is an example of the first decompressing treatment according to the disclosure. The spraying step is an example of the first decompressing step according to the disclosure. Treatment in the spraying step is an example of the first decompressing treatment according to the disclosure.

Step S30: First Pressurizing Step (First Pressurizing Treatment)

Refer to FIG. 12E. The first pressurizing step of the third embodiment is practically the same as the first pressurizing step of the first embodiment. In short, the substrate W is positioned at the first position P1. The decompression unit 81 stops operation and does not decompress the inside of the chamber 3. The supply unit 41 supplies the mixed gas K to the substrate W inside the chamber 3. Accordingly, the inside of the chamber 3 is pressurized from the decompressed state D to the atmospheric pressure state J. The atmosphere inside the chamber 3 includes the organic solvent of the mixed gas K. The substrate W receives the organic solvent of the mixed gas K. For this reason, the substrate W does not dry.

In the first pressurizing step, the lifting/lowering mechanism 15 may cause the substrate W to stand still at the first position P1. Alternatively, in the first pressurizing step, the lifting/lowering mechanism 15 may vertically move or swing the substrate W.

Treatment in the first pressurizing step is an example of the first pressurizing treatment according to the disclosure.

Step S31: Judging Step

The control part 101 judges whether or not the inside of the chamber 3 has shifted to the atmospheric pressure state J based on detection results of the pressure sensor 89. When the control part 101 does not judge that the inside of the chamber 3 has shifted to the atmospheric pressure state J, the procedure returns to Step S30 and continues the first pressurizing step. When the control part 101 judges that the inside of the chamber 3 has shifted to the atmospheric pressure state J, the first pressurizing step ends, and the procedure proceeds to Step S32.

Step S32: First Liquid Discharging Step <First Atmospheric Pressure Step>

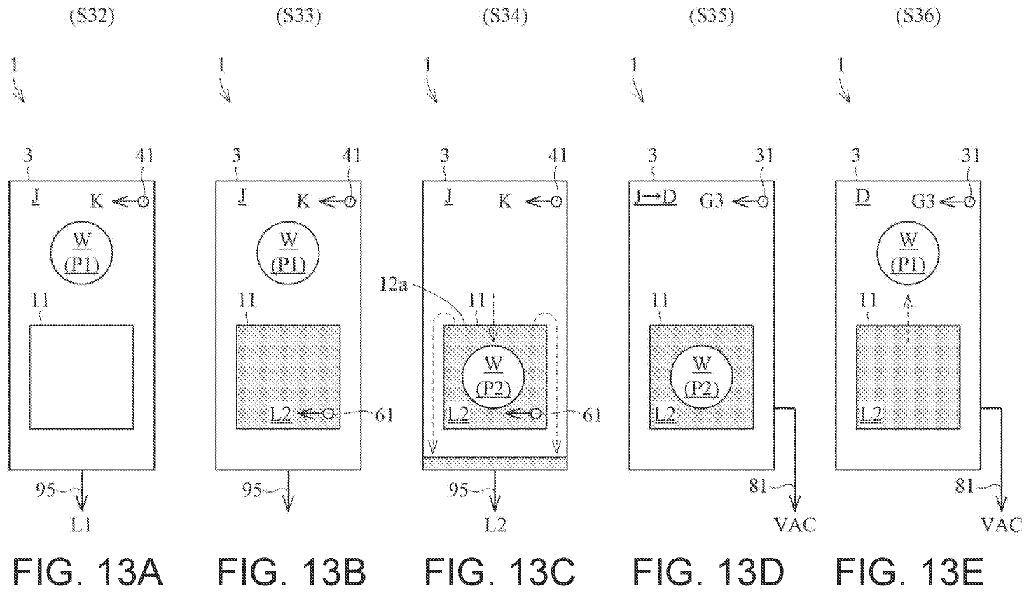

Refer to FIG. 13A. The substrate W is positioned at the first position P1. The supply unit 41 supplies the mixed gas K to the substrate W inside the chamber 3. The decompression unit 81 is at a stop. The inside of the chamber 3 is maintained in the atmospheric pressure state J. The atmosphere inside the chamber 3 includes the organic solvent of the mixed gas K. The liquid discharge unit 95 discharges the first liquid L1 inside the chamber 3 to the outside of the chamber 3. Specifically, the drain valve 97 opens the pipe 99 to the atmospheric air outside the chamber 3. The first liquid L1 accumulated in the bottom part of the chamber 3 is discharged to the outside of the chamber 3 through the pipe 99. In this manner, the first liquid L1 flows from the inside of the chamber 3 to the outside of the chamber 3 through the pipe 99.

The first liquid discharging step of the third embodiment is included in the first atmospheric pressure step of the disclosure.

Step S33: Second Supplying Step <First Atmospheric Pressure Step>

Refer to FIG. 13B. The substrate W is positioned at the first position P1. The supply unit 41 supplies the mixed gas K to the substrate W inside the chamber 3. The decompression unit 81 is at a stop. The inside of the chamber 3 is maintained in the atmospheric pressure state J. The atmosphere inside the chamber 3 includes the organic solvent of the mixed gas K. The dumping valve 92 is closed. The supply unit 61 supplies the second liquid L2 to the treatment tank 11. The treatment tank 11 stores the second liquid L2.

The second supplying step is an example of the supplying step according to the disclosure. The second supplying step is included in the first atmospheric pressure step of the disclosure.

Step S34: Second Dipping Step <First Atmospheric Pressure Step>

Refer to FIG. 13C. The supply unit 41 supplies the mixed gas K to the substrate W inside the chamber 3. The decompression unit 81 is at a stop. The inside of the chamber 3 is maintained in the atmospheric pressure state J. The atmosphere inside the chamber 3 includes the organic solvent of the mixed gas K. The lifting/lowering mechanism 15 moves the substrate W from the first position P1 to the second position P2. The substrate W is dipped into the second liquid L2 inside the treatment tank 11. The second liquid L2 washes the substrate W. For example, the second liquid L2 removes the unreacted water-repellent agent H on the substrate W. For example, the second liquid L2 removes particles derived from the water-repellent agent H on the substrate W.

The liquid discharge unit 95 discharges the second liquid L2 inside the chamber 3 to the outside of the chamber 3. The liquid discharge unit 95 discharges the second liquid L2 which has overflowed from the treatment tank 11 to the outside of the chamber 3. Specifically, the supply unit 61 continuously supplies the second liquid L2 to the treatment tank 11. The dumping valve 92 is closed. The second liquid L2 overflows through the opening 12a of the treatment tank 11. When the second liquid L2 overflows from the treatment tank 11, the water-repellent agent H which has been removed from the substrate W also overflows from the treatment tank 11. When the second liquid L2 overflows from the treatment tank 11, particles which are derived from the water-repellent agent H and have been removed from the substrate W also overflow from the treatment tank 11. The second liquid L2 which has overflowed from the treatment tank 11 is accumulated in the bottom part of the chamber 3. The drain valve 97 is opened. The pipe 99 is open to the atmospheric air outside the chamber 3. The second liquid L2 accumulated in the bottom part of the chamber 3 flows to the outside of the chamber 3 through the pipe 99.

The second dipping step of the third embodiment is included in the first atmospheric pressure step of the disclosure.

Step S35: Atmosphere Forming Step

Refer to FIG. 13D. The substrate W is positioned at the second position P2 and is dipped into the second liquid L2 inside the treatment tank 11. The supply unit 61 stops supplying of the second liquid L2. The drain valve 97 is closed. The supply unit 41 stops supplying of the mixed gas K. The supply unit 31 supplies the treatment gas to the inside of the chamber 3. In this specification, the treatment gas supplied to the chamber 3 after the second dipping step will be suitably referred to as “a third gas G3”. The decompression unit 81 starts operation. The inside of the chamber 3 shifts from the atmospheric pressure state J to the decompressed state D. An atmosphere of the third gas G3 is formed inside the chamber 3.

Step S36: Third Gas Treating Step

Refer to FIG. 13E. The supply unit 31 supplies the third gas G3 to the inside of the chamber 3. The decompression unit 81 is in operation. The inside of the chamber 3 is maintained in the decompressed state D. The lifting/lowering mechanism 15 moves the substrate W from the second position P2 to the first position P1. The substrate W is picked up from the second liquid L2 inside the treatment tank 11. The supply unit 31 supplies the third gas G3 to the substrate W. The substrate W receives the organic solvent derived from the third gas G3. The organic solvent derived from the third gas G3 removes the second liquid L2 on the substrate W. The liquid of the organic solvent derived from the third gas G3 covers the surface of the substrate W.

Step S37: Drying Step

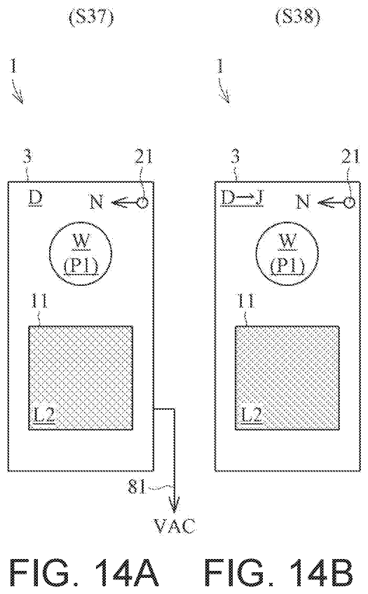

Refer to FIG. 14A. The substrate W is positioned at the first position P1. The decompression unit 81 is in operation. The inside of the chamber 3 is maintained in the decompressed state D. The supply unit 31 stops supplying of the third gas G3. The supply unit 21 supplies the inert gas N. The inert gas N removes the organic solvent on the substrate W. The substrate W dries.

Step S38: Second Pressurizing Step

Refer to FIG. 14B. The substrate W is positioned at the first position P1. The supply unit 21 supplies the inert gas N. The decompression unit 81 stops operation. The inside of the chamber 3 is pressurized from the decompressed state D to the atmospheric pressure state J.

<3-3. Effects of Third Embodiment>

According to the third embodiment, effects similar to those of the first embodiment are exhibited. For example, the inside of the chamber 3 can be appropriately pressurized from the decompressed state D to the atmospheric pressure state J even by the substrate treatment method of the third embodiment. Moreover, according to the third embodiment, the following effects are exhibited.

As described above, the first gas treating step (S25) is an example of the first decompressing step according to the disclosure. In the first gas treating step, in the state D in which the inside of the chamber 3 is decompressed, the substrate W is picked up from the first liquid L1 to above the treatment tank 11. For this reason, the treatment tank 11 stores the first liquid L1 until the substrate W is picked up from the first liquid L1 inside the treatment tank 11 in the first gas treating step. Here, when the substrate W is picked up from the first liquid L1 inside the treatment tank 11 in the first gas treating step, the inside of the chamber 3 is already in the decompressed state D. The treatment tank 11 stores the first liquid L1 until the inside of the chamber 3 shifts to the decompressed state D. As long as the inside of the chamber 3 is in the decompressed state D, it is difficult to discharge the first liquid L1 from the inside of the chamber 3 to the outside of the chamber 3. However, the first pressurizing step is executed after the first gas treating step and before the first liquid discharging step. For this reason, it is easy to execute the first liquid discharging step. In this manner, when the treatment tank 11 stores the first liquid L1 until the inside of the chamber 3 shifts to the decompressed state D, the first pressurizing step is extremely useful.

The substrate treatment method includes the atmosphere forming step of Step S24. Here, the atmosphere forming step of Step S24 will be referred to as the first atmosphere forming step. The first atmosphere forming step is executed before the first gas treating step (S25). In the first atmosphere forming step, the substrate W is dipped into the first liquid L1, and an atmosphere of the first gas G1 is formed inside the chamber 3. For this reason, in the first gas treating step, the substrate W is exposed to the atmosphere of the first gas G1 from when the substrate W is picked up from the first liquid L1 inside the treatment tank 11. Thus, the quality of the substrate treatment in the first gas treating step is favorably improved.

The substrate treatment method includes the second supplying step (S33). The second supplying step is executed after the first liquid discharging step. In the second supplying step, the inside of the chamber 3 is maintained in the atmospheric pressure state J, and the second liquid L2 is supplied to the treatment tank 11. For this reason, the second liquid L2 is supplied to the treatment tank 11 after the first liquid L1 inside the chamber 3 is discharged to the outside of the chamber 3. Thus, it is easy to supply the second liquid L2 to the treatment tank 11 in the second supplying step. Moreover, the inside of the chamber 3 is in the atmospheric pressure state J in the second supplying step. Thus, it is easier to supply the second liquid L2 to the treatment tank 11 in the second supplying step. As a result, it is easy to store the second liquid L2 in the treatment tank 11 in the second supplying step. It is easy to replace the first liquid L1 with the second liquid L2 in the treatment tank 11 by a combination of the first liquid discharging step and the second supplying step.

After the first pressurizing step (S30), the second dipping step (S34) is executed. In the second dipping step, the substrate W is dipped into the second liquid L2 in the treatment tank 11. The mixed gas K is further supplied to the substrate W inside the chamber 3 until the substrate W is dipped into the second liquid L2 in the treatment tank 11 after the first pressurizing step. For this reason, the atmosphere inside the chamber 3 favorably includes the organic solvent until the substrate W is dipped into the second liquid L2 inside the treatment tank 11 after the first pressurizing step. Thus, from the first pressurizing step to the second dipping step, the substrate W does not dry. After the first decompressing step and before the second dipping step, the substrate W does not dry. Therefore, in the second dipping step, the substrate W is treated with appropriate quality.

In the second dipping step, the second liquid L2 is further discharged to the outside of the chamber 3. In the second dipping step, the inside of the chamber 3 is in the atmospheric pressure state J. Thus, in the second dipping step, it is easy to discharge the second liquid L2 inside the chamber 3 to the outside of the chamber 3.

In the second dipping step, the second liquid L2 overflows from the treatment tank 11, and the second liquid L2 which has overflowed from the treatment tank 11 is discharged to the outside of the chamber 3. For this reason, in the second dipping step, it is easy to cleanly maintain the second liquid L2 inside the treatment tank 11. Thus, the quality of the substrate treatment in the second dipping step is favorably improved.

In the second dipping step, the pipe 99 is open to the atmospheric air outside the chamber 3. The pipe 99 communicates with and is connected to the chamber 3. As described above, in the second dipping step, the inside of the chamber 3 is in the atmospheric pressure state J. For this reason, in the second dipping step, due to the dead weight of the second liquid L2, the second liquid L2 flows from the inside of the chamber 3 to the outside of the chamber 3 through the pipe 99. In the second dipping step, the second liquid L2 naturally flows from the inside of the chamber 3 to the outside of the chamber 3 through the pipe 99. In the second dipping step, it is not necessary to forcibly send the second liquid L2 from the inside of the chamber 3 to the outside of the chamber 3. Thus, in the second dipping step, it is easy to discharge the second liquid L2 inside the chamber 3 to the outside of the chamber 3 through the pipe 99.

The disclosure is not limited to the first to third embodiments and can be modified and performed as described below.

(1) In the first and third embodiments, the mixed gas K includes liquid of the organic solvent. In the second embodiment, the mixed gas K includes gas of the organic solvent. However, the disclosure is not limited thereto. The mixed gas K may include at least any of gas of the organic solvent and liquid of the organic solvent. The organic solvent derived from the mixed gas K favorably moistens the substrate W even by this modification embodiment. Thus, the mixed gas K favorably prevents the substrate W from drying.

(2) In the first to third embodiments, the mixed gas K includes the organic solvent. Here, the organic solvent included in the mixed gas K may be a diluted organic solvent. For example, the organic solvent included in the mixed gas K is an organic solvent diluted with deionized water.

Alternatively, the organic solvent included in the mixed gas K may be an undiluted organic solvent. For example, the organic solvent included in the mixed gas K practically consists of only liquid of the organic solvent. For example, the organic solvent included in the mixed gas K is an undiluted solution of an organic solvent. For example, the organic solvent included in the mixed gas K practically includes no water.

(3) In the first to third embodiments, a period of time during which the mixed gas K is supplied to the inside of the chamber 3 has been described as an example. However, the disclosure is not limited thereto. The period of time during which the mixed gas K is supplied to the inside of the chamber 3 may be changed.

In the first embodiment, from the first pressurizing step (S3) to the second decompressing step (S6), the mixed gas K is supplied to the inside of the chamber 3. However, the disclosure is not limited thereto. For example, the mixed gas K may be supplied to the inside of the chamber 3 until the substrate W is dipped into the second liquid L2 inside the treatment tank 11 after the first pressurizing step. Supplying of the mixed gas K may be stopped after the substrate W has been dipped into the second liquid L2 inside the treatment tank 11. According to this modification embodiment, the atmosphere inside the chamber 3 favorably includes the organic solvent of the mixed gas K until the substrate W is dipped into the second liquid L2 inside the treatment tank 11 after the first pressurizing step.

In the second dipping step (S14) of the second embodiment, the mixed gas K is not supplied to the inside of the chamber 3. However, the disclosure is not limited thereto. For example, in the second dipping step (S14), the mixed gas K may be supplied to the chamber 3. According to this modification embodiment, the atmosphere inside the chamber 3 favorably includes the organic solvent of the mixed gas K until the substrate W is dipped into the second liquid L2 inside the treatment tank 11 after the first pressurizing step. From the first pressurizing step to the second dipping step, the atmosphere inside the chamber 3 favorably includes the organic solvent of the mixed gas K.

Alternatively, the mixed gas K may be supplied to the inside of the chamber 3 until the substrate W is dipped into the second liquid L2 inside the treatment tank 11 after the first pressurizing step (S12). Supplying of the mixed gas K may be stopped after the substrate W has been dipped into the second liquid L2 inside the treatment tank 11. Even by this modification embodiment, the atmosphere inside the chamber 3 favorably includes the organic solvent of the mixed gas K until the substrate W is dipped into the second liquid L2 inside the treatment tank 11 after the first pressurizing step.

In the third embodiment, from the first pressurizing step (S30) to the second dipping step (S34), the mixed gas K is supplied to the inside of the chamber 3. However, the disclosure is not limited thereto. For example, the mixed gas K may be supplied to the inside of the chamber 3 until the substrate W is dipped into the second liquid L2 inside the treatment tank 11 after the first pressurizing step. Supplying of the mixed gas K may be stopped after the substrate W has been dipped into the second liquid L2 inside the treatment tank 11. According to this modification embodiment, the atmosphere inside the chamber 3 favorably includes the organic solvent of the mixed gas K until the substrate W is dipped into the second liquid L2 inside the treatment tank 11 after the first pressurizing step.

Alternatively, supplying of the mixed gas K may be stopped after the first pressurizing step (S30). That is, in the first liquid discharging step (S32), the second supplying step (S33), and the second dipping step (S34), the mixed gas K may not be supplied to the inside of the chamber 3. Even by this modification embodiment, from the first pressurizing step to the second dipping step, the atmosphere inside the chamber 3 favorably includes the organic solvent of the mixed gas K. In the case of this modification embodiment, in the first pressurizing step, an atmosphere of the mixed gas K is formed inside the chamber 3. In the first liquid discharging step, the second supplying step, and the second dipping step, the inside of the chamber 3 is not decompressed. In the first liquid discharging step, the second supplying step, and the second dipping step, the gas inside the chamber 3 is not discharged to the outside of the chamber 3. For this reason, the atmosphere of the mixed gas K remains inside the chamber 3 until the second dipping step after the first pressurizing step. Thus, the atmosphere inside the chamber 3 favorably includes the organic solvent of the mixed gas K until the second dipping step after the first pressurizing step even by this modification embodiment.

(4) In the first embodiment, the pipe 96 of the liquid discharge unit 95 communicates with and is connected to the treatment tank 11. In the first liquid discharging step (S5) of the first embodiment, the first liquid L1 inside the treatment tank 11 is discharged to the outside of the chamber 3 through the pipe 96. However, the disclosure is not limited thereto. For example, the pipe 96 may communicate with and be connected to the chamber 3. For example, the pipe 96 may be changed to a constitution similar to that of the pipe 99 of the third embodiment. For example, in the first liquid discharging step of the first embodiment, the first liquid L1 accumulated in the chamber 3 may be discharged to the outside of the chamber 3 through the pipe 96.

(5) In the third embodiment, the pipe 99 of the liquid discharge unit 95 communicates with and is connected to the chamber 3. In the first liquid discharging step (S32) of the third embodiment, the first liquid L1 accumulated in the chamber 3 is discharged to the outside of the chamber 3 through the pipe 99. In the second dipping step (S34) of the third embodiment, the second liquid L2 accumulated in the chamber 3 is discharged to the outside of the chamber 3 through the pipe 99. However, the disclosure is not limited thereto. For example, the pipe 99 may communicate with and be connected to the treatment tank 11. For example, the pipe 99 may be changed to a constitution similar to that of the pipe 96 of the first embodiment. For example, in the first liquid discharging step of the third embodiment, the first liquid L1 inside the treatment tank 11 may be discharged to the outside of the chamber 3 through the pipe 99. For example, in the second dipping step of the third embodiment, the second liquid L2 inside the treatment tank 11 may be discharged to the outside of the chamber 3 through the pipe 99.

(6) In the first and third embodiments, a rinse liquid and deionized water have been described as examples of the first liquid L1 to be supplied to the treatment tank 11. However, the disclosure is not limited thereto. For example, the first liquid L1 may be a diluted organic solvent. For example, the first liquid L1 may be an organic solvent diluted with deionized water.

(7) In the first to third embodiments, a diluted organic solvent has been described as an example of the second liquid L2 to be supplied to the treatment tank 11. However, the disclosure is not limited thereto. For example, the second liquid L2 may be a rinse. For example, the second liquid L2 may be deionized water.

(8) In the first to third embodiments, the constitutions of the supply units 21, 31, 41, 61, and 71 have been described as examples. However, the disclosure is not limited thereto. The constitutions of the supply units 21, 31, 41, 61, and 71 may be suitably changed.

In the first to third embodiments, the inert gas N, the first gas G1, the mixed gas K, and the water-repellent agent H are emitted from the emission parts 22, 32, 42, 52, and 72 different from each other. However, the disclosure is not limited thereto. At least two of the inert gas N, the first gas G1, the mixed gas K, and the water-repellent agent H may be emitted from the same emission part.

The supply unit 61 supplies the generated second liquid L2 to the treatment tank 11. However, the disclosure is not limited thereto. The supply unit 61 may generate the second liquid L2 inside the treatment tank 11. For example, the supply unit 61 may individually supply the undiluted organic solvent and deionized water to the treatment tank 11.

In the spraying step (S29) of the third embodiment, the mixed gas K is sprayed over the substrate W inside the chamber 3. However, the disclosure is not limited thereto. For example, in the spraying step, a third liquid may be sprayed over the substrate W inside the chamber 3. For example, in the spraying step, the third liquid may be sprayed without being accompanied by the inert gas. For example, in the spraying step, the third liquid may be sprayed through the shower head nozzles. Here, for example, the third liquid includes liquid of the organic solvent.

(9) The first and third embodiments and each of the modification embodiments described in the foregoing (1) to (8) may be suitably changed by further replacing or combining each constituent with a constituent of other modification embodiments.

The disclosure can be performed in other specific forms without departing from the spirit and the essence thereof, and therefore the appended claims should be referred to instead of the foregoing description so as to indicate the scope of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents

### REFERENCE SIGNS LIST

1 Substrate treatment device

3 Chamber

11 Treatment tank

31 Supply unit (first supply unit)

41 Supply unit (second supply unit)

42 Emission part (first emission part)

52 Emission part (first emission part)

61 Supply unit

81 Decompression unit

89 Pressure sensor

95 Liquid discharge unit

96 Pipe (liquid discharge tube)

99 Pipe (liquid discharge tube)

101 Control part

D Decompressed state

G1 First gas

G2 Second gas

J Atmospheric pressure state

K Mixed gas

L1 First liquid

L2 Second liquid

P1 First position

P2 Second position

W Substrate

What is claimed is:

1. A substrate treatment method for simultaneously treating a plurality of substrates accommodated in one chamber, the substrate treatment method comprising:
a first decompressing step of supplying a first gas including an organic solvent to the substrate inside the chamber in a state in which the inside of the chamber is decompressed;
a first pressurizing step of supplying mixed gas including an organic solvent and inert gas to the substrate inside the chamber and pressurizing the inside of the chamber from a decompressed state to an atmospheric pressure state after the first decompressing step; and
a first atmospheric pressure step of maintaining the inside of the chamber in an atmospheric pressure state and performing at least any of liquid discharge treatment and substrate treatment after the first pressurizing step.

2. The substrate treatment method according to claim 1,
wherein the mixed gas includes at least any of gas of the organic solvent and liquid of the organic solvent.

3. The substrate treatment method according to claim 1,
wherein in the first pressurizing step, the mixed gas is generated and the generated mixed gas is supplied to the inside of the chamber by a first emission part.

4. The substrate treatment method according to claim 1,
wherein in the first pressurizing step, the substrate is further vertically moved or swung inside the chamber.

5. The substrate treatment method according to claim 1 further comprising:
a first dipping step of dipping the substrate into a first liquid stored in a treatment tank installed inside the chamber before the first decompressing step,
wherein the first atmospheric pressure step further includes a first liquid discharging step of discharging the first liquid to the outside of the chamber.

6. The substrate treatment method according to claim 5,
wherein in the first liquid discharging step, a liquid discharge tube which communicates with and is connected to any of the chamber and the treatment tank is open to atmospheric air outside the chamber and the first liquid is discharged to the outside of the chamber through the liquid discharge tube.

7. The substrate treatment method according to claim 5,
wherein in the first decompressing step, the substrate is picked up from the first liquid to above the treatment tank in a state in which the inside of the chamber is decompressed.

8. The substrate treatment method according to claim 7 further comprising:
a first atmosphere forming step of forming an atmosphere of the first gas inside the chamber in a state in which the substrate is dipped into the first liquid before the first decompressing step.

9. The substrate treatment method according to claim 5,
wherein the first atmospheric pressure step further includes a supplying step of supplying a second liquid to the treatment tank after the first liquid discharging step.

10. The substrate treatment method according to claim 9,
wherein the first atmospheric pressure step further includes a second dipping step of dipping the substrate into the second liquid stored in the treatment tank.

11. The substrate treatment method according to claim 10,
wherein an atmosphere inside the chamber includes an organic solvent until the substrate is dipped into the second liquid from the first pressurizing step.

12. The substrate treatment method according to claim 11,
wherein the mixed gas is further supplied to the substrate inside the chamber until the substrate is dipped into the second liquid from the first pressurizing step.

13. The substrate treatment method according to claim 10,
wherein in the second dipping step, the second liquid is further discharged to the outside of the chamber.

14. The substrate treatment method according to claim 1,
wherein the first atmospheric pressure step further includes a second dipping step of dipping the substrate into a second liquid stored in a treatment tank installed inside the chamber.

15. The substrate treatment method according to claim 14,
wherein in the second dipping step, the second liquid is further discharged to the outside of the chamber.

16. The substrate treatment method according to claim 15,
wherein in the second dipping step, the second liquid overflows from the treatment tank and the second liquid which has overflowed from the treatment tank is discharged to the outside of the chamber.

17. The substrate treatment method according to claim 15,
wherein in the second dipping step, a liquid discharge tube which communicates with and is connected to any of the chamber and the treatment tank is open to atmospheric air outside the chamber and the second liquid is discharged to the outside of the chamber through the liquid discharge tube.

18. The substrate treatment method according to claim 1 further comprising:
a second decompressing step of dipping the substrate into a second liquid stored in a treatment tank installed inside the chamber in a state in which the inside of the chamber is decompressed after the first atmospheric pressure step.

19. The substrate treatment method according to claim 18,
wherein an atmosphere inside the chamber includes an organic solvent until the substrate is dipped into the second liquid from the first pressurizing step.

20. A substrate treatment device comprising:
a chamber that accommodates a plurality of substrates;
a decompression unit that decompresses the inside of the chamber;
a first supply unit that supplies a first gas including an organic solvent to the substrate inside the chamber;
a second supply unit that supplies mixed gas including an organic solvent and inert gas to the substrate inside the chamber; and
a control part that controls the decompression unit, the first supply unit, and the second supply unit to execute first decompressing treatment and first pressurizing treatment,
wherein in the first decompressing treatment, the decompression unit decompresses the inside of the chamber, and the first supply unit supplies the first gas to the substrate, and
wherein in the first pressurizing treatment, the decompression unit does not decompress the inside of the chamber, and the second supply unit supplies the mixed gas to the substrate.
